(19) United States
(12) Patent Application Publication
(10) Pub. No.: US 2025/0176165 A1
(43) Pub. Date: May 29, 2025

(54) INTEGRATED CIRCUIT DEVICE

(71) Applicant: SAMSUNG ELECTRONICS CO., LTD., Suwon-si (KR)

(72) Inventors: Jihye Lee, Suwon-si (KR); Yangdoo Kim, Suwon-si (KR); Sangwuk Park, Suwon-si (KR); Minkyu Suh, Suwon-si (KR); Geonyeop Lee, Suwon-si (KR); Dokeun Lee, Suwon-si (KR); Jewoo Han, Suwon-si (KR)

(21) Appl. No.: 18/940,262

(22) Filed: Nov. 7, 2024

(30) Foreign Application Priority Data
Nov. 23, 2023 (KR) 10-2023-0164495

(51) Int. Cl. H10B 12/00

(52) U.S. Cl. CPC H10B 12/315; H10B 12/033

(57) ABSTRACT

An integrated circuit device includes a lower electrode above a substrate, a plurality of insulating support patterns supporting the lower electrode and spaced apart from each other in a vertical direction, a plurality of bridge patterns each having a thickness less than a thickness of each of the plurality of insulating support patterns in the vertical direction and respectively interposed between the plurality of insulating support patterns and the lower electrode, a capacitor dielectric layer covering the lower electrode, the plurality of insulating support patterns, and the plurality of bridge patterns, and an upper electrode facing the lower electrode with the capacitor dielectric layer therebetween.

### CROSS-REFERENCE TO RELATED APPLICATION

This application claims priority under 35 U.S.C. § 119 to Korean Patent Application No. 10-2023-0164495, filed on Nov. 23, 2023, in the Korean Intellectual Property Office, the disclosure of which is incorporated by reference herein in its entirety.

### BACKGROUND

Along with the development of electronic technologies, downscaling of semiconductor devices has rapidly progressed, and accordingly, patterns in electronic devices have been miniaturized. Accordingly, there is a need to develop a structure with improved reliability of a capacitor having a miniaturized size.

### SUMMARY

The disclosure provides an integrated circuit device with improved reliability and including a capacitor with a miniaturized size.

The disclosure also provides a method of manufacturing an integrated circuit device with improved reliability and including a capacitor with a miniaturized size.

According to an aspect of the disclosure, there is provided an integrated circuit device including a lower electrode above a substrate, a plurality of insulating support patterns supporting the lower electrode and spaced apart from each other in a vertical direction, a plurality of bridge patterns each having a thickness less than a thickness of each of the plurality of insulating support patterns in the vertical direction and respectively interposed between the plurality of insulating support patterns and the lower electrode, a capacitor dielectric layer covering the lower electrode, the plurality of insulating support patterns, and the plurality of bridge patterns, and an upper electrode facing the lower electrode with the capacitor dielectric layer therebetween.

According to another aspect of the disclosure, there is provided an integrated circuit device including an upper insulating support pattern spaced apart from an upper surface of a substrate in a vertical direction and having a plurality of holes, a plurality of lower electrodes extending above the substrate in the vertical direction through the plurality of holes respectively, a plurality of upper bridge patterns between the upper insulating support pattern and the plurality of lower electrodes in the plurality of holes, respectively, a capacitor dielectric layer covering the upper insulating support pattern, the plurality of lower electrodes, and the plurality of upper bridge patterns, and an upper electrode facing the plurality of lower electrodes with the capacitor dielectric layer therebetween, wherein each of the plurality of lower electrodes includes an upper portion in each of the plurality of holes and a lower portion extending downward from the upper portion in the vertical direction and having a horizontal width narrower than that of the upper portion.

According to another aspect of the disclosure, there is provided an integrated circuit device including a substrate including an active region, a plurality of conductive regions formed on the active region, an etch stop pattern extending in a horizontal direction on the plurality of conductive regions and having a plurality of lower holes vertically overlapping the plurality of conductive regions, respectively, a plurality of lower electrodes connected to the plurality of conductive regions through the plurality of lower holes, respectively, a plurality of capping patterns between the etch stop pattern and the plurality of lower electrodes in the plurality of lower holes, respectively, an upper insulating support pattern extending in the horizontal direction at a location spaced apart from the etch stop pattern in a vertical direction, and having a plurality of holes accommodating the plurality of holes therein, respectively, a plurality of upper bridge patterns between the plurality of lower electrodes and the upper insulating support pattern in the plurality of lower holes, respectively, and each having a thickness in the vertical direction less than a thickness of the upper insulating support pattern in the vertical direction, a capacitor dielectric layer covering the plurality of lower electrodes, the etch stop pattern, the plurality of capping patterns, the upper insulating support pattern, and the plurality of upper bridge patterns, and an upper electrode facing the plurality of lower electrodes with the capacitor dielectric layer therebetween.

### BRIEF DESCRIPTION OF THE DRAWINGS

Implementations of the disclosure will be more clearly understood from the following detailed description taken in conjunction with the accompanying drawings in which:

FIG. 1 is a schematical top view layout for describing some components in a memory cell array area of an integrated circuit device according some implementations;

FIG. 2A is a top view illustrating some components of the integrated circuit device shown in FIG. 1;

FIG. 2B is a cross-sectional view taken along line X1-X1′ of FIG. 2A and schematically illustrating some components;

FIG. 3A is a magnified cross-sectional view of an area indicated by “EX1A” in FIG. 2B;

FIG. 3B is a magnified cross-sectional view of an area indicated by “EX1B” in FIG. 2B;

FIG. 3C is a magnified cross-sectional view of an area indicated by “EX1C” in FIG. 2B;

FIG. 4A is a top view illustrating some components of an integrated circuit device according to some implementations;

FIG. 4B is a cross-sectional view taken along line X2-X2′ of FIG. 4A and schematically illustrating some components;

FIG. 5A is a magnified cross-sectional view of an area indicated by “EX2A” in FIG. 4B;

FIG. 5B is a magnified cross-sectional view of an area indicated by “EX2B” in FIG. 4B;

FIG. 5C is a magnified cross-sectional view of an area indicated by “EX2C” in FIG. 4B;

FIG. 6A is a top view illustrating some components of an integrated circuit device according to some implementations;

FIG. 6B is a cross-sectional view taken along line X3-X3′ of FIG. 6A and schematically illustrating some components;

FIG. 7 is a magnified cross-sectional view of an area indicated by “EX3A” in FIG. 6B;

FIGS. 8A to 13 illustrate, in a process order, a method of manufacturing an integrated circuit device according some implementations, wherein FIGS. 8A, 9A, and 11A are top-view layout diagrams illustrating, in the process order, some components to describe the method of manufacturing an integrated circuit device, and FIGS. 8B, 9B, 10, 11B, 12, and 13 are cross-sectional views illustrating, in the process order, a portion corresponding to line X1-X1′ of FIG. 2A;

FIGS. 14A and 14B are cross-sectional views illustrating, in a process order, a portion corresponding to line X2-X2′ of FIG. 4A to describe a method of manufacturing an integrated circuit device, according to some implementations; and

FIGS. 15A to 15E are cross-sectional views illustrating, in a process order, a portion corresponding to line X3-X3′ of FIG. 6A to describe a method of manufacturing an integrated circuit device, according to some implementations.

### DETAILED DESCRIPTION

Hereinafter, Implementations are described in detail with reference to the accompanying drawings. Like reference numerals in the drawings denote like elements, and thus their repetitive description will be omitted.

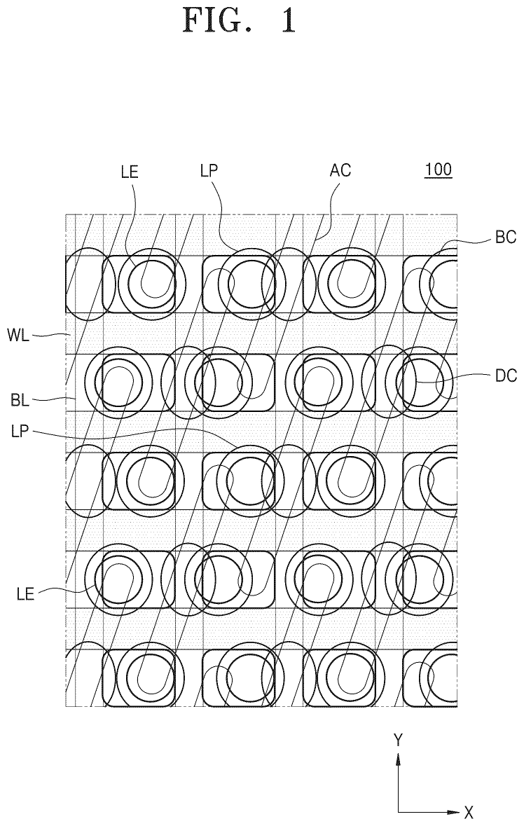

FIG. 1 is a schematical top view layout for describing some components in a memory cell array area of an integrated circuit device 100 according some implementations.

Referring to FIG. 1, the integrated circuit device 100 includes a plurality of active regions AC arranged to horizontally extend in a diagonal direction with respect to a first horizontal direction (an X direction) and a second horizontal direction (a Y direction) perpendicular to each other in a top view. A plurality of word lines WL may extend in the first horizontal direction (the X direction) by crossing the plurality of active regions AC and be parallel to each other in the second horizontal direction (the Y direction). On the plurality of word lines WL, a plurality of bit lines BL may extend in the second horizontal direction (the Y direction) and be parallel to each other in the first horizontal direction (the X direction). Each of the plurality of bit lines BL may be connected to an active region AC through a direct contact DC.

A plurality of buried contacts BC may be formed between two adjacent bit lines BL among the plurality of bit lines BL. A plurality of conductive landing pads LP may be formed on the plurality of buried contacts BC, respectively. Each of the plurality of conductive landing pads LP may at least partially overlap a buried contact BC. A plurality of lower electrodes LE spaced apart from each other may be formed on the plurality of conductive landing pads LP, respectively. The plurality of lower electrodes LE may be respectively connected to the plurality of active regions AC through the plurality of buried contacts BC and the plurality of conductive landing pads LP.

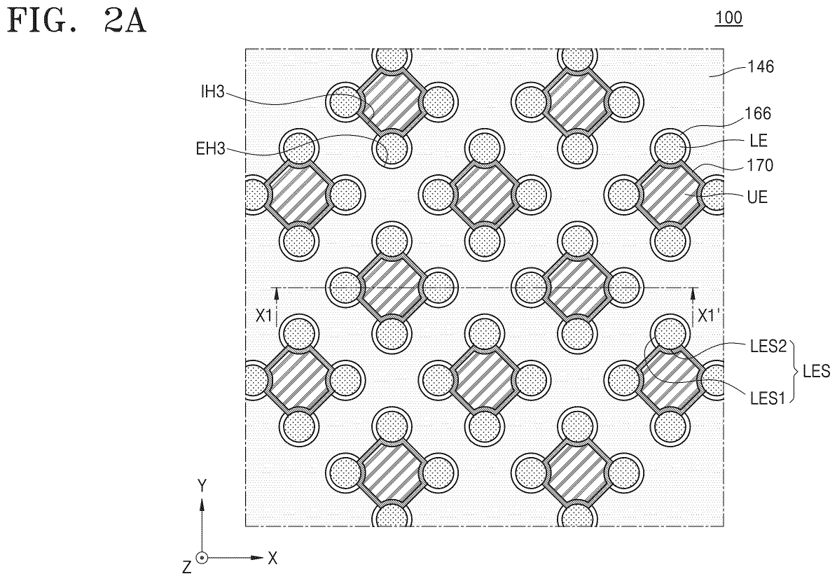

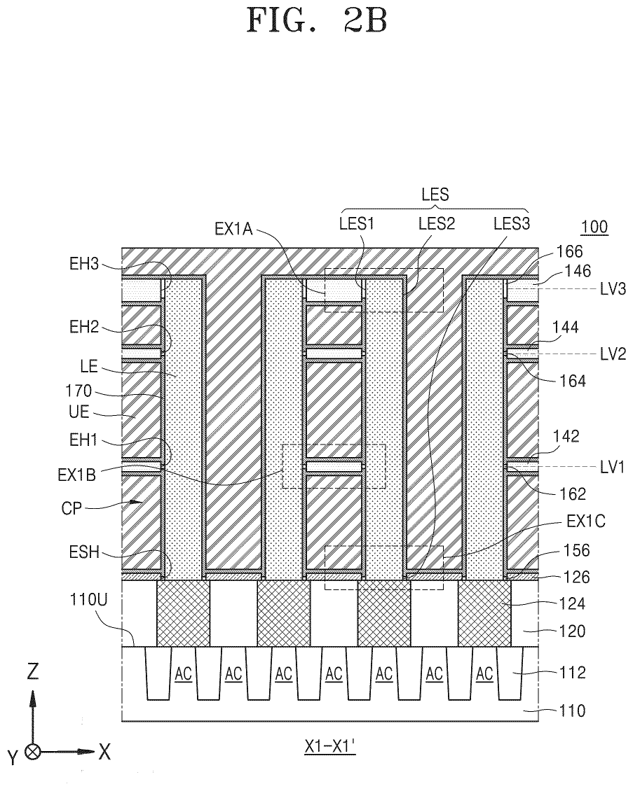

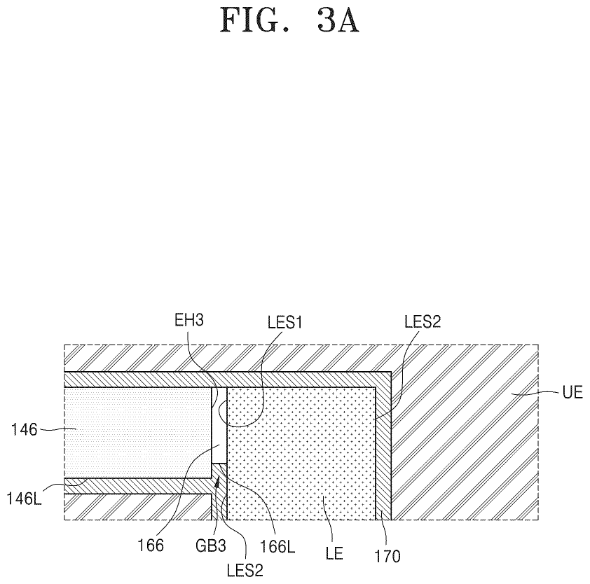

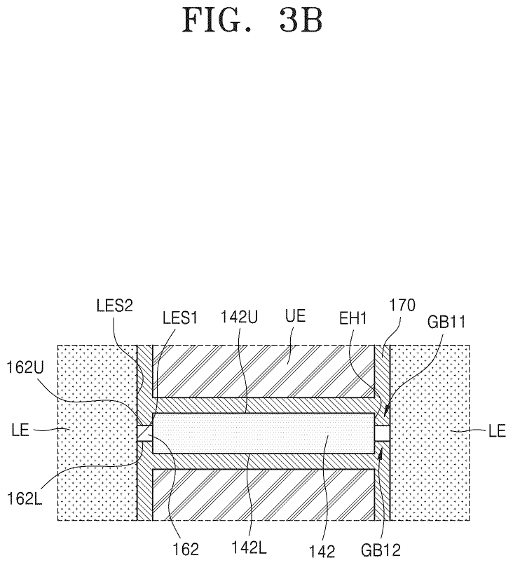

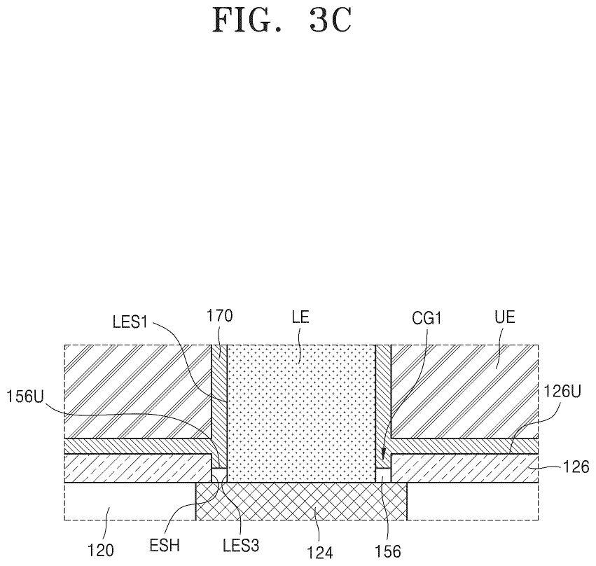

FIG. 2A is a top view illustrating some components of the integrated circuit device 100 shown in FIG. 1. FIG. 2B is a cross-sectional view taken along line X1-X1′ of FIG. 2A and schematically illustrating some components. FIG. 3A is a magnified cross-sectional view of an area indicated by “EX1A” in FIG. 2B. FIG. 3B is a magnified cross-sectional view of an area indicated by “EX1B” in FIG. 2B. FIG. 3C is a magnified cross-sectional view of an area indicated by “EX1C” in FIG. 2B.

Referring to FIGS. 2A to 3C, the integrated circuit device 100 may further include a substrate 110 including the plurality of active regions AC and a lower structure 120 formed on the substrate 110. A plurality of conductive regions 124 may be respectively connected to the plurality of active regions AC by penetrating the lower structure 120 in a vertical direction (a Z direction).

In some implementations, the substrate 110 may include a semiconductor element, such as silicon (Si) or germanium (Ge), or a compound semiconductor, such as silicon carbide (SiC), gallium arsenide (GaAs), indium arsenide (InAs), or indium phosphide (InP). The substrate 110 may include a semiconductor substrate and structures including at least one insulating layer or at least one conductive region formed on the semiconductor substrate. The at least one conductive region may include, for example, an impurity-doped well or an impurity-doped structure. A device isolation layer 112 defining the plurality of active regions AC may be formed in the substrate 110. The device isolation layer 112 may include an oxide layer, a nitride layer, or a combination thereof.

In some implementations, the lower structure 120 may include an insulating layer made of a silicon oxide (SiO) layer, a silicon nitride (SiN) layer, or a combination thereof. In some implementations, the lower structure 120 may include various conductive regions, e.g., a wiring layer, a contact plug, and a transistor, and insulating layers mutually insulating the various conductive regions. The plurality of conductive regions 124 may include polysilicon, a metal, conductive metal nitride, metal silicide, or a combination thereof. The lower structure 120 may include, for example, the plurality of bit lines BL described with reference to FIG. 1. Each of the plurality of conductive regions 124 may include, for example, the buried contact BC and the conductive landing pad LP described with reference to FIG. 1.

According some implementations, the integrated circuit device 100 includes a plurality of capacitors CP on the plurality of conductive regions 124. The plurality of capacitors CP include the plurality of lower electrodes LE, a capacitor dielectric layer 170, and an upper electrode UE covering the capacitor dielectric layer 170. According some implementations, each of the plurality of lower electrodes LE may extend upward in the vertical direction (the Z direction) from one selected from among the plurality of conductive regions 124. Each of the plurality of lower electrodes LE may be in contact with and connected to a corresponding conductive region 124 among the plurality of conductive regions 124. According some implementations, the plurality of lower electrodes LE may be spaced apart from each other in a horizontal direction (the X direction and/or the Y direction) on the lower structure 120. According some implementations, the capacitor dielectric layer 170 may be between the plurality of lower electrodes LE and the upper electrode UE.

According some implementations, the integrated circuit device 100 includes an etch stop layer 126, a plurality of capping patterns 156, a plurality of insulating support patterns, e.g., first to third insulating support patterns 142, 144, and 146, and a plurality of first to third bridge patterns 162, 164, and 166, the etch stop pattern 126 and the plurality of capping patterns 156 covering the lower structure 120. The first to third insulating support patterns 142, 144, and 146 and the plurality of first to third bridge patterns 162, 164, and 166 may be configured to support the plurality of lower electrodes LE. The capacitor dielectric layer 170 may cover the etch stop pattern 126, the plurality of capping patterns 156, the first to third insulating support patterns 142, 144, and 146, and the plurality of first to third bridge patterns 162, 164, and 166. Referring to FIGS. 2A and 2B, a sidewall LES of each of the plurality of lower electrodes LE includes a first portion LES1 in contact with the plurality of first to third bridge patterns 162, 164, and 166, a second portion LES2 in contact with the capacitor dielectric layer 170, and a third portion LES3 in contact with the plurality of capping patterns 156.

According some implementations, the etch stop pattern 126 may be adjacent to a lower end portion of each of the plurality of lower electrodes LE and have a plurality of lower holes ESH individually overlapping the plurality of conductive regions 124 in the vertical direction (the Z direction), respectively. Each of the plurality of lower electrodes LE may be connected to a corresponding conductive region 124 among the plurality of conductive regions 124 through any one selected from among the plurality of lower holes ESH. For example, the etch stop pattern 126 may surround the lower end portion of each of the plurality of lower electrodes LE, and each of the plurality of capping patterns 156 may be between the etch stop pattern 126 and a corresponding lower electrode LE among the plurality of lower electrodes LE.

In some implementations, each of the plurality of lower electrodes LE may have a pillar shape elongating from the upper surface of a corresponding conductive region 124 in a direction away from the substrate 110 through a corresponding lower hole ESH among the plurality of lower holes ESH of the etch stop pattern 126. Although FIG. 2B illustrates that each of the plurality of lower electrodes LE has a pillar shape, the technical idea of the disclosure is not limited thereto. For example, each of the plurality of lower electrodes LE may have a cup shape or a cylindrical shape with a closed bottom portion.

According some implementations, the plurality of capping patterns 156 may be individually between the etch stop pattern 126 and the plurality of lower electrodes LE in the plurality of lower holes ESH, respectively. For example, each of the plurality of capping patterns 156 may surround the third portion LES3 of a corresponding lower electrode LE among the plurality of lower electrodes LE. The inner walls of the plurality of lower holes ESH may be spaced apart from the third portions LES3 of the plurality of lower electrodes LE with the plurality of capping patterns 156 therebetween, respectively. For example, the third portion LES3 of each of the plurality of lower electrodes LE may be spaced apart from the etch stop pattern 126 with a corresponding capping pattern 156 among the plurality of capping patterns 156 therebetween. In some implementations, the plurality of capping patterns 156 may overlap the plurality of conductive regions 124 in the vertical direction (the Z direction), respectively. The upper electrode UE may be spaced apart from the plurality of conductive regions 124 with the capacitor dielectric layer 170 and the plurality of capping patterns 156 therebetween. In some implementations, each of the plurality of capping patterns 156 may have a ring shape in a top view.

In some implementations, the thickness of each of the plurality of capping patterns 156 in the vertical direction (the Z direction) may be less than the thickness of the etch stop pattern 126 in the vertical direction (the Z direction). In some implementations, an upper surface 156U of each of the plurality of capping patterns 156 may be at a vertical level lower than that of an upper surface 126U of the etch stop pattern 126. The inner wall of each of the plurality of lower holes ESH may include a first portion in contact with a corresponding capping pattern 156 among the plurality of capping patterns 156 and a second portion facing a corresponding lower electrode LE among the plurality of lower electrodes LE with the capacitor dielectric layer 170 therebetween. For example, the second portion may face the second portion LES2 of the lower electrode LE. On each of the plurality of capping patterns 156, there may be a gap CG1 limited by the upper surface 156U of the capping pattern 156, the second portion of the inner wall of a lower hole ESH, and the second portion LES2 of a lower electrode LE. In some implementations, the gap CG1 may be filled with the capacitor dielectric layer 170, and the second portion of the inner wall of each of the plurality of lower holes ESH may face the sidewall of each of the plurality of lower electrodes LE with the capacitor dielectric layer 170 therebetween. In the specification, the term “vertical level” indicates a distance in a Z direction or −Z direction from an upper surface 110U of the substrate 110.

In some implementations, the etch stop pattern 126 may include a SiN layer, a silicon boron nitride (SiBN) layer, or a combination thereof. The terms “SiN” and “SiBN” used in the specification indicate materials made of elements included in the respective terms but are not chemical formulae indicating stoichiometric relationships.

According some implementations, first to third insulating support patterns 142, 144, and 146 may be above the lower structure 120 so as to be spaced apart from each other in the vertical direction (the Z direction). The first insulating support pattern 142 may be spaced apart from the etch stop pattern 126 in the vertical direction (the Z direction).

According some implementations, the first to third insulating support patterns 142, 144, and 146 may extend in the horizontal direction (the X direction and/or the Y direction) at different vertical levels. The first insulating support pattern 142 may have a plurality of first holes EH1, the second insulating support pattern 144 may have a plurality of second holes EH2, and the third insulating support pattern 146 may have a plurality of third holes EH3. In some implementations, the plurality of first holes EH1, the plurality of second holes EH2, the plurality of third holes EH3, and the plurality of lower holes ESH may accommodate the plurality of lower electrodes LE, respectively. The plurality of first holes EH1, the plurality of second holes EH2, the plurality of third holes EH3, and the plurality of lower holes ESH may overlap each other in the vertical direction (the Z direction). For example, each of the plurality of lower electrodes LE may extend in the vertical direction (the Z direction) through one selected from among the plurality of first holes EH1, one selected from among the plurality of second holes EH2, one selected from among the plurality of third holes EH3, and one selected from among the plurality of lower holes ESH and be in contact with a corresponding conductive region 124 among the plurality of conductive regions 124.

According some implementations, in the plurality of first holes EH1 of the first insulating support pattern 142, the plurality of first bridge patterns 162 may be between a corresponding lower electrode LE among the plurality of lower electrodes LE and the first insulating support pattern 142, respectively. The plurality of lower electrodes LE may be spaced apart from the first insulating support pattern 142 with the plurality of first bridge patterns 162 at a first vertical level LV1 at which the plurality of first bridge patterns 162 are disposed. For example, at the first vertical level LV1, the first portion LES1 of each of the plurality of lower electrodes LE may be in contact with a corresponding first bridge pattern 162 among the plurality of first bridge patterns 162.

According some implementations, the plurality of second bridge patterns 164 may be disposed at a second vertical level LV2 higher than the first vertical level LV1 and be in contact with the second insulating support pattern 144 and the plurality of lower electrodes LE. In the plurality of second holes EH2 of the second insulating support pattern 144, the plurality of second bridge patterns 164 may be between a corresponding lower electrode LE among the plurality of lower electrodes LE and the second insulating support pattern 144, respectively. The plurality of lower electrodes LE may be spaced apart from the second insulating support pattern 144 with the plurality of second bridge patterns 164 therebetween at the second vertical level LV2. For example, at the second vertical level LV2, the first portion LES1 of each of the plurality of lower electrodes LE may be in contact with a corresponding second bridge pattern 164 among the plurality of second bridge patterns 164.

According some implementations, the plurality of third bridge patterns 166 may be disposed at a third vertical level LV3 higher than the second vertical level LV2 and be in contact with the third insulating support pattern 146 and the plurality of lower electrodes LE. In the plurality of third holes EH3 of the third insulating support pattern 146, the plurality of third bridge patterns 166 may be between a corresponding lower electrode LE among the plurality of lower electrodes LE and the third insulating support pattern 146, respectively. The plurality of lower electrodes LE may be spaced apart from the third insulating support pattern 146 with the plurality of third bridge patterns 166 therebetween at the third vertical level LV3. For example, at the third vertical level LV3, the first portion LES1 of each of the plurality of lower electrodes LE may be in contact with a corresponding third bridge pattern 166 among the plurality of first bridge patterns 162.

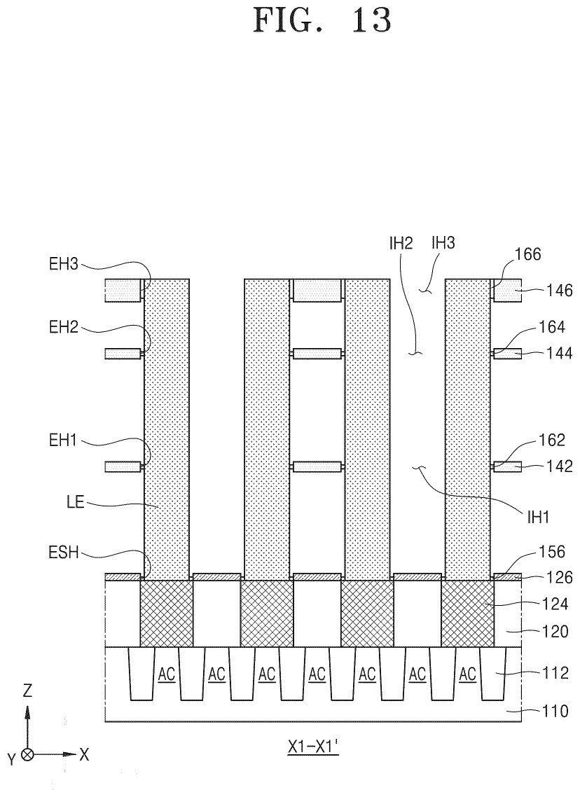

According some implementations, the first insulating support pattern 142 includes a plurality of first integrated holes IH1 (see FIG. 13) each connecting some of the plurality of first holes EH1 to each other, the second insulating support pattern 144 includes a plurality of second integrated holes IH2 (see FIG. 13) each connecting some of the plurality of second holes EH2 to each other, and the third insulating support pattern 146 includes a plurality of third integrated holes IH3 each connecting some of the plurality of third holes EH3 to each other. The plurality of first, second, and third integrated holes IH1, IH2, and IH3 (see FIG. 13) may overlap each other in the vertical direction (the Z direction) and accommodate the upper electrode UE therein.

FIG. 2A shows a plane structure of the third insulating support pattern 146, the plurality of third bridge patterns 166, the plurality of lower electrodes LE, the upper electrode UE, and the capacitor dielectric layer 170 at the third vertical level LV3. Referring to FIGS. 2A and 2B, the upper electrode UE may be inside the plurality of third integrated holes IH3 and surrounded by the third insulating support pattern 146 with the capacitor dielectric layer 170 therebetween. According some implementations, at the third vertical level LV3, the sidewall LES of each of the plurality of lower electrodes LE includes the first portion LES1 in contact with each of the plurality of third bridge patterns 166 and the second portion LES2 facing the upper electrode UE. In a top view, each of the plurality of third bridge patterns 166 may have a ring shape of which a portion is cut by one selected from among the plurality of third integrated holes IH3. For example, the plurality of third bridge patterns 166 may have an open ring shape. Referring to FIG. 2A, at the third vertical level LV3, the capacitor dielectric layer 170 may include portions in contact with the inner walls of the plurality of third integrated holes IH3, portions in contact with the second portions LES2 of the plurality of lower electrodes LE, and portions in contact with end portions of the plurality of third bridge patterns 166.

FIG. 2A illustrates that a plane shape of each of the plurality of third integrated holes IH3 is a schematic lozenge shape with adjacent four lower electrodes LE at the respective vertices thereof. However, the plane shape of each of the plurality of third integrated holes IH3 is not limited to FIG. 2A and may be variously modified and changed within the scope of the technical idea of the disclosure.

The plurality of first integrated holes IH1 (see FIG. 13) of the first insulating support pattern 142 and the plurality of second integrated holes IH2 (see FIG. 13) of the second insulating support pattern 144 may have a plane shape corresponding to the plane shape of the plurality of third integrated holes IH3 shown in FIG. 2A.

For example, at the first vertical level LV1, the upper electrode UE may be inside the plurality of first integrated holes IH1 and surrounded by the first insulating support pattern 142 with the capacitor dielectric layer 170 therebetween. The sidewall LES of each of the plurality of lower electrodes LE includes the first portion LES1 in contact with each of the plurality of first bridge patterns 162 and the second portion LES2 in contact with the capacitor dielectric layer 170 and facing the upper electrode UE. Each of the plurality of first bridge patterns 162 may have a ring shape of which a portion is cut by one selected from among the plurality of first integrated holes IH1 (see FIG. 13) in a top view, end portions of the plurality of first bridge patterns 162 may be spaced apart from the upper electrode UE with the capacitor dielectric layer 170 therebetween.

Although FIG. 2B illustrates that the integrated circuit device 100 comprises three insulating support patterns (the first to third insulating support patterns 142, 144, and 146) above the lower structure 120, the technical idea of the disclosure is not limited thereto. For example, the integrated circuit device 100 may include any number of insulating support patterns other than the three insulating support patterns.

In some implementations, the thickness of each of the plurality of first bridge patterns 162 in the vertical direction (the Z direction) may be less than the thickness of the first insulating support pattern 142 in the vertical direction (the Z direction), and the thickness of each of the plurality of second bridge patterns 164 may be less than the thickness of the second insulating support pattern 144 in the vertical direction (the Z direction). In some implementations, the thickness of each of the plurality of third bridge patterns 166 in the vertical direction (the Z direction) may be less than the thickness of the third insulating support pattern 146 in the vertical direction (the Z direction).

Referring to FIG. 3A, the upper surfaces of the plurality of lower electrodes LE may be coplanar with the upper surface of the third insulating support pattern 146. In some implementations, the upper surfaces of the plurality of third bridge patterns 166 may be coplanar with the upper surfaces of the plurality of lower electrodes LE and the upper surface of the third insulating support pattern 146.

In some implementations, a lower surface 146L of the third insulating support pattern 146 may be at a vertical level lower than that of a lower surface 166L of each of the plurality of third bridge patterns 166. In some implementations, the inner wall of each of the plurality of third holes EH3 of the third insulating support pattern 146 may include a first portion in contact with a corresponding third bridge pattern 166 among the plurality of third bridge patterns 166 and a second portion facing the sidewall LES of a corresponding lower electrode LE among the plurality of lower electrodes LE. For example, the second portion may face the second portion LES2 of the sidewall LES of the lower electrode LE. Beneath each of the plurality of third bridge patterns 166, there may be a bridge gap GB3 limited by the lower surface 166L of the third bridge pattern 166, the second portion of the inner wall of the third hole EH3, and the second portion LES2 of the sidewall LES of the lower electrode LE. In some implementations, the capacitor dielectric layer 170 may fill the bridge gap GB3 and be in contact with the lower surface 166L of each of the plurality of third bridge patterns 166. In some implementations, the second portion of the inner wall of the third hole EH3 may face the lower electrode LE with the capacitor dielectric layer 170 therebetween.

Referring to FIG. 3B, an upper surface 162U of each of the plurality of first bridge patterns 162 may be at a vertical level lower than that of an upper surface 142U of the first insulating support pattern 142, and a lower surface 162L of each of the plurality of first bridge patterns 162 may be at a vertical level higher than that of a lower surface 142L of the first insulating support pattern 142. In some implementations, the inner wall of each of the plurality of first holes EH1 of the first insulating support pattern 142 may include a first portion in contact with a corresponding first bridge pattern 162 among the plurality of first bridge patterns 162, a second portion on the first portion and facing a corresponding lower electrode LE among the plurality of lower electrodes LE with the capacitor dielectric layer 170 therebetween, and a third portion beneath the first portion and facing the corresponding lower electrode LE with the capacitor dielectric layer 170 therebetween. In some implementations, on each of the plurality of first bridge patterns 162, there may be a first bridge gap GB11 limited by the upper surface 162U of the first bridge pattern 162, the second portion of the inner wall of a corresponding first hole EH1, and a portion of the sidewall LES of the corresponding lower electrode LE. In some implementations, beneath each of the plurality of first bridge patterns 162, there may be a second bridge gap GB12 limited by the lower surface 162L of the first bridge pattern 162, the third portion of the inner wall of the corresponding first hole EH1, and a portion of the sidewall LES of the corresponding lower electrode LE. For example, the first bridge gap GB11 and the second bridge gap GB12 may face each other with each of the plurality of first bridge patterns 162 therebetween. In some implementations, the capacitor dielectric layer 170 may fill the first bridge gap GB11 and the second bridge gap GB12. For example, each of the second portion and the third portion of the inner wall of each of the plurality of first holes EH1 may be in contact with the capacitor dielectric layer 170 and face the sidewall LES of a corresponding lower electrode LE with the capacitor dielectric layer 170 therebetween.

The structure of the second insulating support pattern 144 and the plurality of second bridge patterns 164 may be generally the same as the first insulating support pattern 142 and the plurality of first bridge patterns 162 described with reference to FIG. 2C. In the specification, the first insulating support pattern 142 and the second insulating support pattern 144 may be referred to as a lower insulating support pattern, and the plurality of first bridge patterns 162 and the plurality of second bridge patterns 164 may be referred to as a plurality of lower bridge patterns. In the specification, the third insulating support pattern 146 may be referred to as an upper insulating support pattern, and the plurality of third bridge patterns 166 may be referred to as a plurality of upper bridge patterns.

Although FIGS. 2B and 3A to 3C show that portions of the capacitor dielectric layer 170 filling the gap CG1, the first bridge gap GB11, the second bridge gap GB12, and the bridge gap GB3 are formed with thicknesses greater than, for example, the thickness of a portion of the capacitor dielectric layer 170 covering the upper surface of the lower electrode LE, the technical idea of the disclosure is not limited thereto. For example, the capacitor dielectric layer 170 may be formed with a constant thickness and have a profile corresponding to surfaces forming the gap CG1, the first bridge gap GB11, the second bridge gap GB12, and the bridge gap GB3.

Although FIGS. 2A to 3C illustrate that the thickness of the capacitor dielectric layer 170 is substantially the same as each of the thicknesses of the plurality of first to third bridge patterns 162, 164, and 166 in the horizontal direction (the X direction and/or the Y direction), the technical idea of the disclosure is not limited thereto. For example, each of the thicknesses of the plurality of first to third bridge patterns 162, 164, and 166 in the horizontal direction (the X direction and/or the Y direction) may be greater than the thickness of the capacitor dielectric layer 170.

In some implementations, each of the first to third insulating support patterns 142, 144, and 146 may include a SiN layer, a SiBN layer, or a combination thereof. In some implementations, the first to third insulating support patterns 142, 144, and 146 may include the same material. In some implementations, at least some of the first to third insulating support patterns 142, 144, and 146 may include different materials. However, the technical idea of the disclosure is not limited to the materials described above.

In some implementations, each of the plurality of first to third bridge patterns 162, 164, and 166 and the plurality of capping patterns 156 may include a SiO layer, a SiN layer, or a combination thereof. In some implementations, the plurality of first to third bridge patterns 162, 164, and 166 may include the same material.

In some implementations, each of the plurality of first to third bridge patterns 162, 164, and 166 may include a single layer. In some implementations, each of the plurality of first to third bridge patterns 162, 164, and 166 may include multiple layers respectively including different materials.

In some implementations, the capacitor dielectric layer 170 may include a high dielectric layer. The term “high dielectric layer” used in the specification indicates a dielectric layer having a dielectric constant higher than that of a SiO layer. In some implementations, the capacitor dielectric layer 170 may include metal oxide including at least one metal selected from among hafnium (Hf), zirconium (Zr), aluminum (Al), niobium (Nb), cerium (Ce), lanthanum (La), tantalum (Ta), and titanium (Ti).

In some implementations, each of the lower electrode LE and the upper electrode UE may include a metal layer, a conductive metal oxide layer, a conductive metal nitride layer, a conductive metal oxynitride layer, or a combination thereof. In some implementations, each of the lower electrode LE and the upper electrode UE may include Nb, Nb oxide, Nb nitride, Nb oxynitride, Ti, Ti oxide, Ti nitride, Ti oxynitride, cobalt (Co), Co oxide, Co nitride, Co oxynitride, tin (Sn), Sn oxide, Sn nitride, Sn oxynitride, or a combination thereof. For example, each of the lower electrode LE and the upper electrode UE may include niobium nitride (NbN), titanium nitride (TiN), cobalt nitride (CoN), tine dioxide (SnO₂), or a combination thereof. In some implementations, each of the lower electrode LE and the upper electrode UE may include tantalum nitride (TaN), titanium aluminum nitride (TiAlN), tantalum aluminum nitride (TaAlN), vanadium (V), vanadium nitride (VN), molybdenum (Mo), molybdenum nitride (MoN), tungsten (W), tungsten nitride (WN), ruthenium (Ru), ruthenium dioxide (RuO₂), strontium ruthenium trioxide (SrRuO₃ (SRO)), iridium (Ir), iridium dioxide (IrO₂), platinum (Pt), platinum oxide (PtO), barium strontium ruthenium trioxide ((Ba,Sr)RuO₃ (BSRO)), calcium ruthenium trioxide (CaRuO₃ (CRO)), lanthanum strontium cobalt trioxide ((La,Sr)CoO₃ (LSCO)), or a combination thereof. However, the constituent material of each of the lower electrode LE and the upper electrode UE is not limited to the materials described above.

The integrated circuit device 100 according some implementations includes the plurality of first to third bridge patterns 162, 164, and 166 between the plurality of lower electrodes LE and the first to third insulating support patterns 142, 144, and 146. The plurality of first to third bridge patterns 162, 164, and 166 may cover the inner walls of the plurality of first to third holes EH1, EH2, and EH3 with a certain thickness, respectively, and be in contact with the first portions LES1 of the plurality of lower electrodes LE. In a process of forming the plurality of lower electrodes LE having a high aspect ratio, the plurality of first to third bridge patterns 162, 164, and 166 may partially fill the plurality of first to third holes EH1, EH2, and EH3 such that the plurality of lower electrodes LE having a relatively narrow width in the horizontal direction (the X direction and/or the Y direction) are formed with relatively low process difficulty. In addition, the separation distance between adjacent lower electrodes LE among the plurality of lower electrodes LE may be ensured by the plurality of first to third bridge patterns 162, 164, and 166, thereby improving the reliability of the integrated circuit device 100.

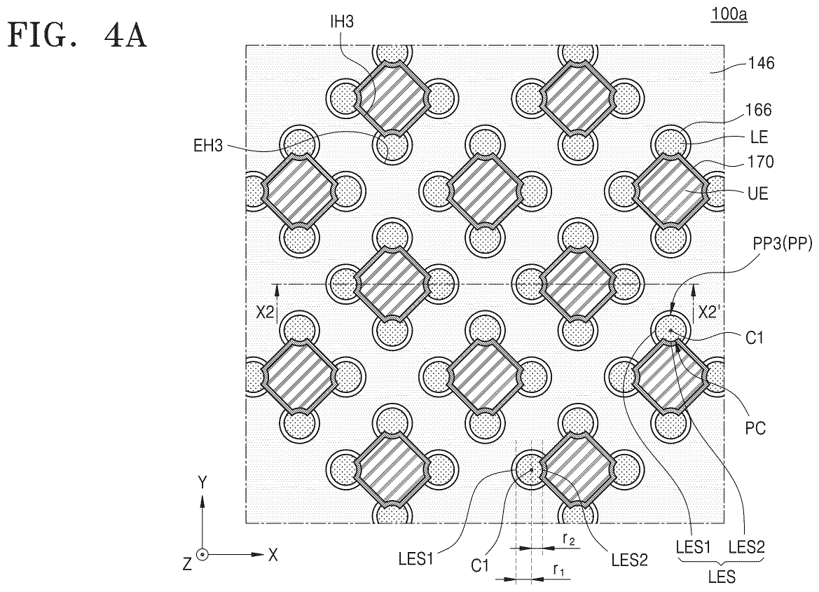

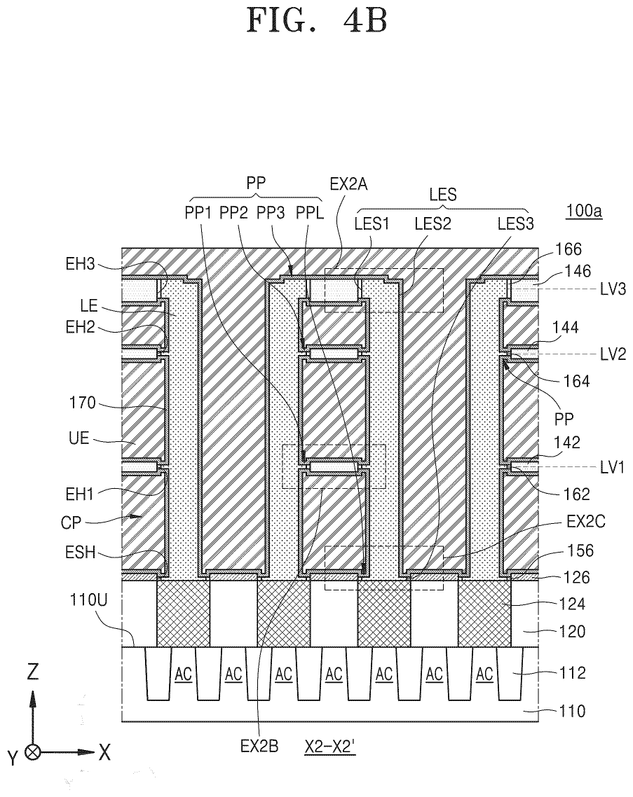

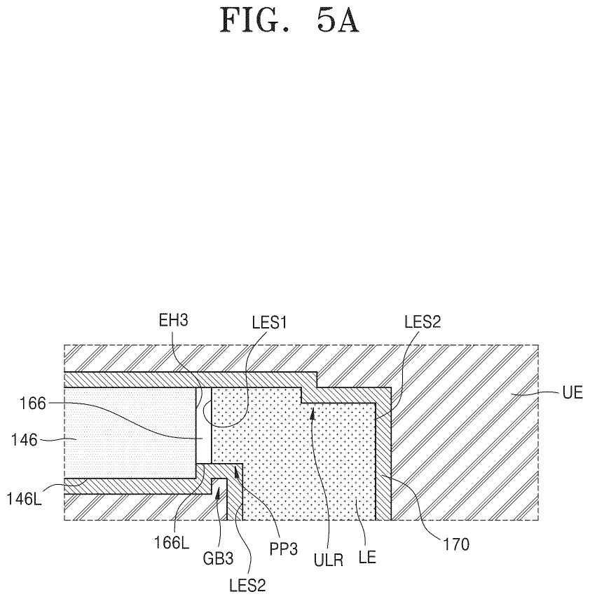

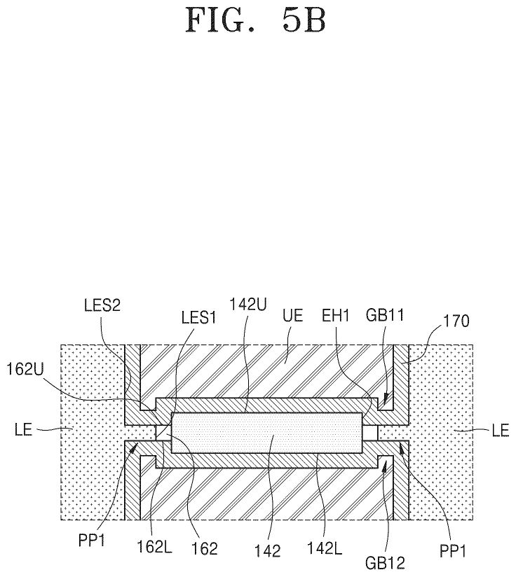

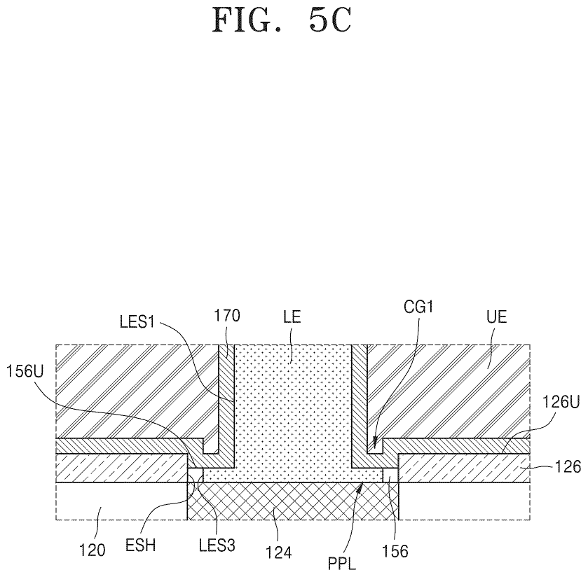

FIG. 4A is a top view illustrating some components of an integrated circuit device 100a according to some implementations. FIG. 4B is a cross-sectional view schematically illustrating some components taken along line X2-X2′ of FIG. 4A. FIG. 5A is a magnified cross-sectional view of an area indicated by “EX2A” in FIG. 4B. FIG. 5B is a magnified cross-sectional view of an area indicated by “EX2B” in FIG. 4B. FIG. 5C is a magnified cross-sectional view of an area indicated by “EX2C” in FIG. 4B. In FIGS. 4A to 5C, like reference numerals in FIGS. 1 to 3C denote like elements, and thus their repetitive description will be omitted.

Referring to FIGS. 4A to 5C, each of the plurality of lower electrodes LE of the integrated circuit device 100a includes a plurality of protrusion portions PP protruding from the second portion LES2 of the sidewall LES in a direction away from a center C1 of each of the plurality of lower electrodes LE.

According some implementations, the plurality of protrusion portions PP include a lower-end protrusion portion PPL in contact with the capping pattern 156 in the lower hole ESH, a first protrusion portion PP1 in contact with the first bridge pattern 162 in the first hole EH1, a second protrusion portion PP2 in contact with the second bridge pattern 164 in a second hole EH2, and a third protrusion portion PP3 in contact with the third bridge pattern 166 in the third hole EH3. For example, the first portion LES1 of the sidewall LES of each of the plurality of lower electrodes LE may be formed as outer walls of the first to third protrusion portions PP1, PP2, and PP3 and be in contact with the first to third bridge patterns 162, 164, and 166. For example, the third portion LES3 of the sidewall LES of each of the plurality of lower electrodes LE may be formed as the outer wall of the lower-end protrusion portion PPL and be in contact with the capping pattern 156. In some implementations, the plurality of protrusion portions PP may face the etch stop pattern 126 and the first to third insulating support patterns 142, 144, and 146 with the plurality of capping patterns 156 and the plurality of first to third bridge patterns 162, 164, and 166 therebetween.

According some implementations, the lower-end protrusion portion PPL may face the inner wall of a corresponding lower hole ESH among the plurality of lower holes ESH of the etch stop pattern 126 with a corresponding capping pattern 156 among the plurality of capping patterns 156 therebetween. The first protrusion portion PP1 may face the inner wall of a corresponding first hole EH1 among the plurality of first holes EH1 of the first insulating support pattern 142 with a corresponding first bridge pattern 162 among the plurality of first bridge patterns 162 therebetween. The second protrusion portion PP2 may face the inner wall of a corresponding second hole EH2 among the plurality of second holes EH2 of the second insulating support pattern 144 with a corresponding second bridge pattern 164 among the plurality of second bridge patterns 164 therebetween. The third protrusion portion PP3 may face the inner wall of a corresponding third hole EH3 among the plurality of third holes EH3 of the third insulating support pattern 146 with a corresponding third bridge pattern 166 among the plurality of third bridge patterns 166 therebetween.

Referring to FIGS. 4A and 4B, respective third protrusion portions PP3 of two lower electrodes LE selected from among the plurality of lower electrodes LE and spaced apart from each other with the third insulating support pattern 146 therebetween may face each other. For example, a third protrusion portion PP3 of a first lower electrode LE selected from among the plurality of lower electrodes LE may face a third protrusion portion PP3 of a second lower electrode LE selected from among the plurality of lower electrodes LE, arranged adjacent to the first lower electrode LE, and spaced apart from the first lower electrode LE in the horizontal direction (the X direction and/or the Y direction) with the third insulating support pattern 146 therebetween. Between the third protrusion portion PP3 of the first lower electrode LE and the third protrusion portion PP3 of the second lower electrode LE, there may be a third bridge pattern 166 in contact with the first lower electrode LE among the plurality of third bridge patterns 166, the third insulating support pattern 146, and a third bridge pattern 166 in contact with the second lower electrode LE among the plurality of third bridge patterns 166.

Referring to FIG. 4B, respective first protrusion portions PP1 of two lower electrodes LE among the plurality of lower electrodes LE, which are arranged adjacent to each other and spaced apart from each other with the first insulating support pattern 142 therebetween, may face each other. Respective second protrusion portions PP2 of two lower electrodes LE among the plurality of lower electrodes LE, which are arranged adjacent to each other and spaced apart from each other with the second insulating support pattern 144 therebetween, may face each other.

FIG. 4A illustrates a plane structure of third protrusions PP3 of the plurality of lower electrodes LE at the third vertical level LV3. In some implementations, in a top view, a first distance r1 that is the distance from the center C1 of each of the plurality of lower electrodes LE to the first portion LES1 of the sidewall LES may be greater than a second distance r2 that is the distance from the center C1 to the second portion LES2 of the sidewall LES. In some implementations, each of the plurality of lower electrodes LE includes a recessed portion PC limited by the third protrusion portion PP3 and the second portion LES2 of the sidewall LES in a top view. For example, the recessed portion PC may have a shape recessed toward the center C1 rather than the third protrusion portion PP3 in a top view. For example, at the third vertical level LV3, each of the plurality of lower electrodes LE may have a circular shape of which a portion is cut.

In some implementations, at the third vertical level LV3, respective recessed portions PC of two lower electrodes LE among the plurality of lower electrodes LE, which are arranged adjacent to each other and spaced apart from each other with the upper electrode UE therebetween, may face each other.

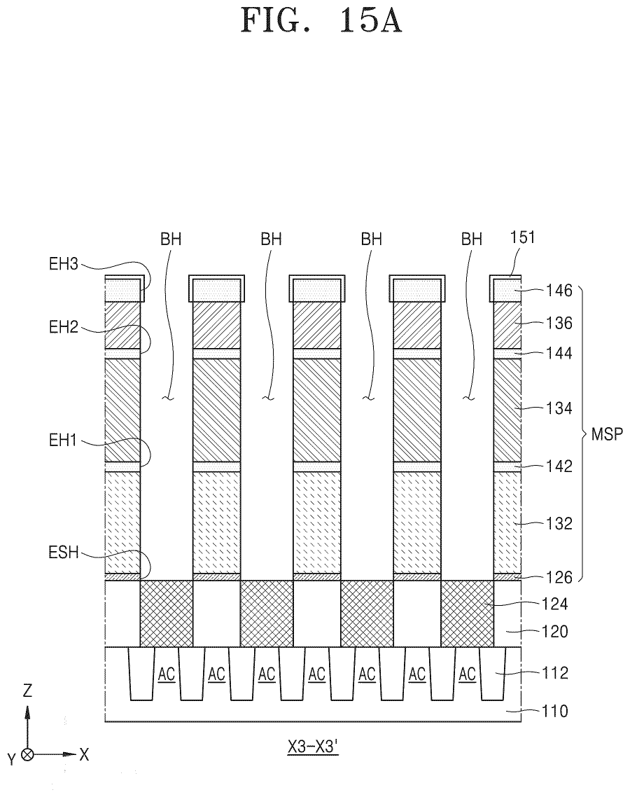

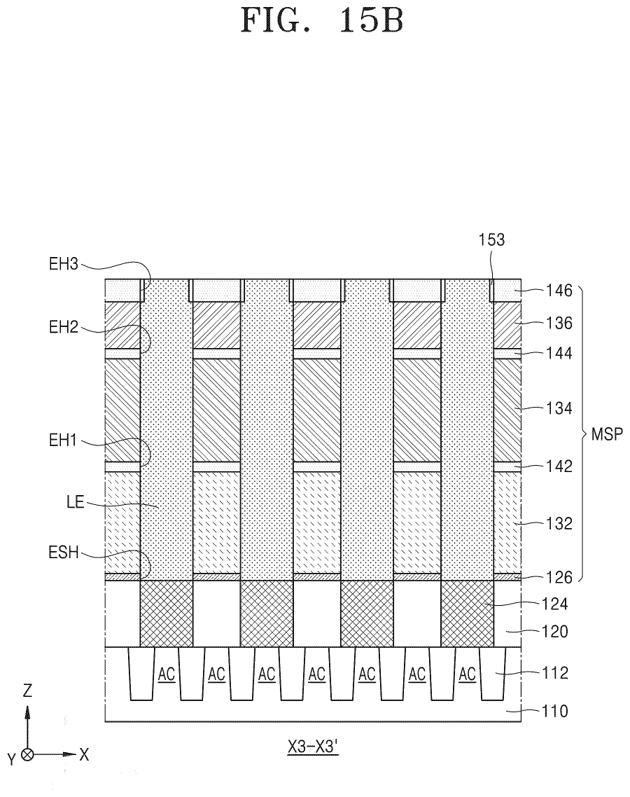

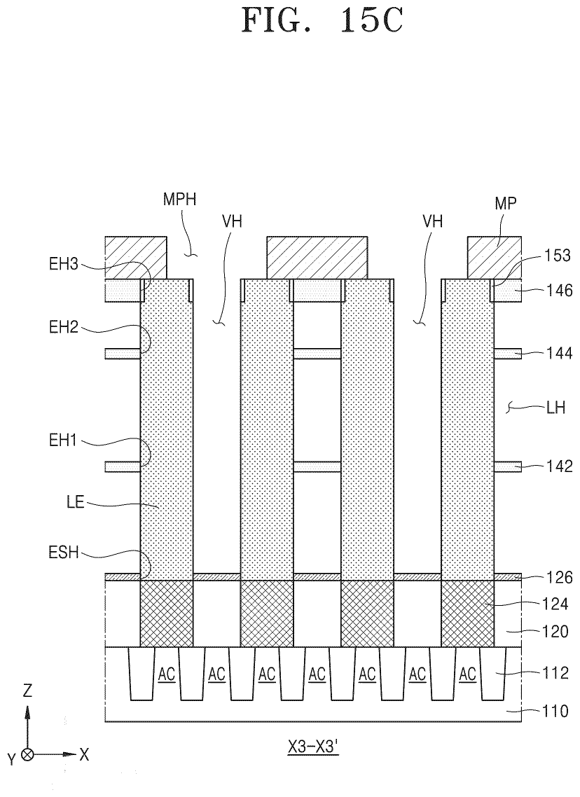

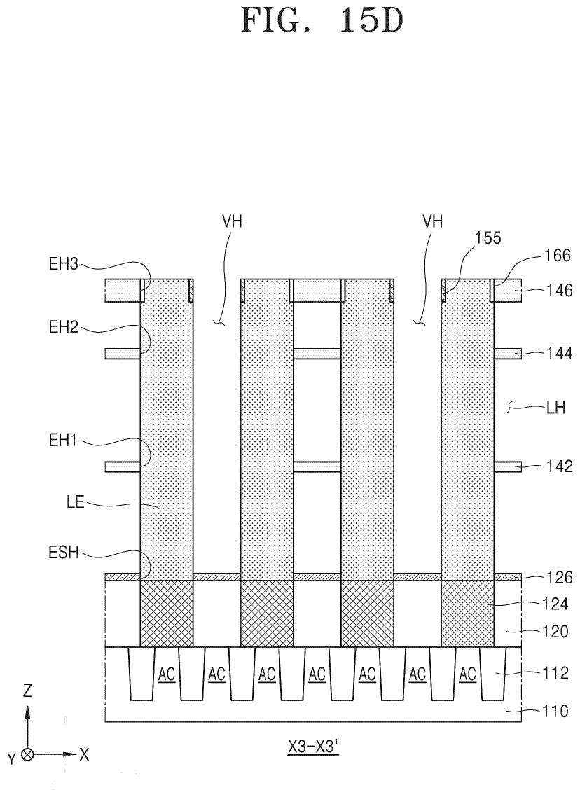

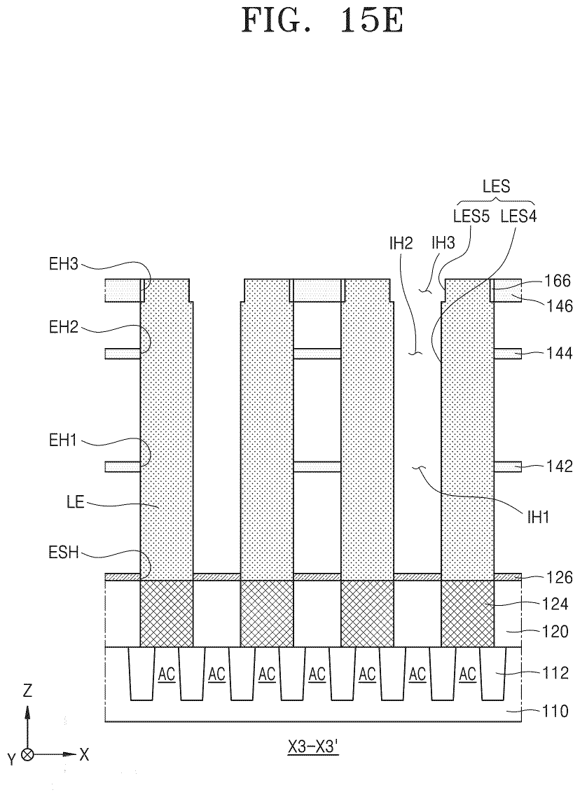

The plane shape of the plurality of lower electrodes LE facing the first insulating support pattern 142 and the upper electrode UE at the first vertical level LV1 and the plane shape of the plurality of lower electrodes LE facing the second insulating support pattern 144 and the upper electrode UE at the second vertical level LV2 may correspond to the plane shape, shown in FIG. 4A, of the plurality of lower electrodes LE facing the third insulating support pattern 146 and the upper electrode UE at the third vertical level LV3. Although not shown, at the first vertical level LV1, each of the plurality of lower electrodes LE may have a recessed portion defined by the first protrusion portion PP1 and facing a first integrated hole IH1 (see FIG. 15E), and at the second vertical level LV2, each of the plurality of lower electrodes LE may have a recessed portion defined by the second protrusion portion PP2 and facing a second integrated hole IH2 (see FIG. 15E). At each vertical level, at least some of recessed portions may face each other.

In some implementations, each of the plurality of capping patterns 156 may have a closed ring shape in a top view. The outer wall of each of the plurality of capping patterns 156 may be in contact with the inner wall of each of the plurality of lower holes ESH, and the inner wall of each of the plurality of capping patterns 156 may be in contact with the third portion LES3 that is the outer wall of the lower-end protrusion portion PPL. In some implementations, the lower-end protrusion portion PPL may be at a fourth vertical level, and at the fourth vertical level, the distance from the center C1 of each of the plurality of lower electrodes LE to the sidewall LES may be identical regardless of an azimuth with respect to the center C1.

In some implementations, a portion of the lower-end protrusion portion PPL, the first protrusion portion PP1, the second protrusion portion PP2, and the third protrusion portion PP3 may overlap each other in the vertical direction (the Z direction). However, the technical idea of the disclosure is not limited thereto. For example, each of the plurality of lower electrodes LE may have a conical shape or a prismoidal shape having a horizontal width decreasing away from the upper surface 110U of the substrate 110, and in this case, the portion of the lower-end protrusion portion PPL, the first protrusion portion PP1, the second protrusion portion PP2, and the third protrusion portion PP3 may not overlap each other in the vertical direction (the Z direction).

Referring to FIG. 5A, each of the plurality of lower electrodes LE may have a recess ULR on the upper surface thereof. Referring to FIGS. 4A and 5A, a first region between the center C1 and the second portion LES2 may be defined in a top view. For example, the first region may have a fan shape. In some implementations, the recess ULR may vertically overlap the first region. In some implementations, the bottom surface of the recess ULR may be at a vertical level lower than that of the upper surface of the third insulating support pattern 146 and the upper surfaces of the plurality of third bridge patterns 166. The recess ULR may be filled with the capacitor dielectric layer 170 and the upper electrode UE.

Referring to FIG. 5A, the bridge gap GB3 may be limited by the lower surface of the third protrusion portion PP3, the lower surface 166L of the third bridge pattern 166, the inner wall of the third hole EH3, and a portion of the sidewall LES of the lower electrode LE. In some implementations, the lower surface of the third protrusion portion PP3 may be in contact with the capacitor dielectric layer 170 filling the third hole EH3.

Although FIG. 5A illustrates that the thickness of the third protrusion portion PP3 in the vertical direction (the Z direction) may be substantially the same as the thickness of the third bridge pattern 166 in the vertical direction (the Z direction), the technical idea of the disclosure is not limited thereto. In some implementations, the lower surface of the third protrusion portion PP3 may be at a lower vertical level than that of the lower surface 166L of the third bridge pattern 166. In some implementations, the lower surface of the third protrusion portion PP3 may be at a vertical level higher than that of the lower surface 166L of the third bridge pattern 166. For example, the lower surface 166L of the third bridge pattern 166 and the lower surface of the third protrusion portion PP3 may form a stepped structure.

Referring to FIG. 5B, the first bridge gap GB11 may be limited by the upper surface of the first protrusion portion PP1, the upper surface 162U of the first bridge pattern 162, a portion of the inner wall of the first hole EH1, and a portion of the sidewall LES of the lower electrode LE, and the second bridge gap GB12 may be limited by the lower surface of the first protrusion portion PP1, the lower surface 162L of the first bridge pattern 162, a portion of the inner wall of the first hole EH1, and a portion of the sidewall LES of the lower electrode LE. Although FIG. 5B illustrates that the thickness of the first protrusion portion PP1 in the vertical direction (the Z direction) may be substantially the same as the thickness of the first bridge pattern 162 in the vertical direction (the Z direction), the technical idea of the disclosure is not limited thereto.

The second insulating support pattern 144, the plurality of second bridge patterns 164, and the second protrusion portion PP2 may have generally the same structures as described above with respect to the first insulating support pattern 142, the plurality of first bridge patterns 162, and the first protrusion portion PP1, respectively.

Referring to FIG. 5C, the gap CG1 may be limited by the upper surface of the lower-end protrusion portion PPL, the upper surface 156U of the capping pattern 156, a portion of the inner wall of the lower hole ESH of the etch stop pattern 126, and a portion of the sidewall LES of the lower electrode LE. Although FIG. 5C illustrates that the thickness of the lower protrusion portion PPL in the vertical direction (the Z direction) may be substantially the same as the thickness of the capping pattern 156 in the vertical direction (the Z direction), the technical idea of the disclosure is not limited thereto.

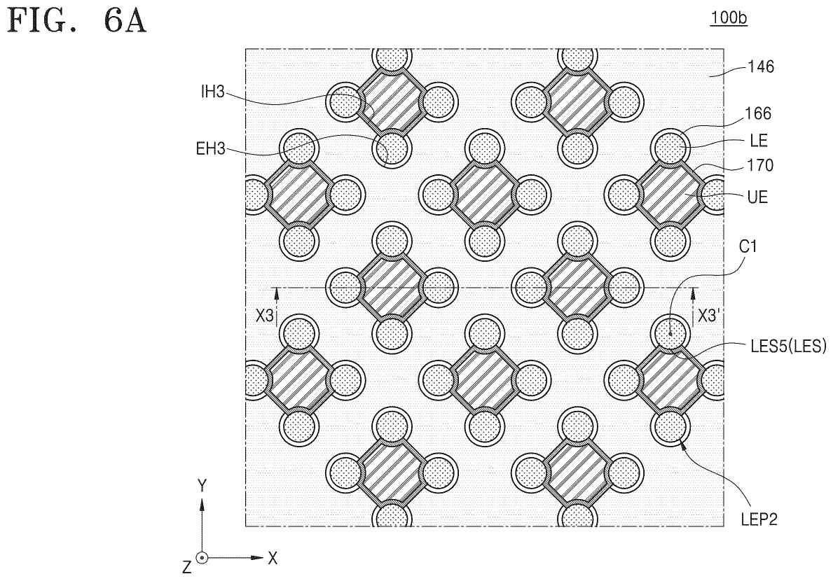

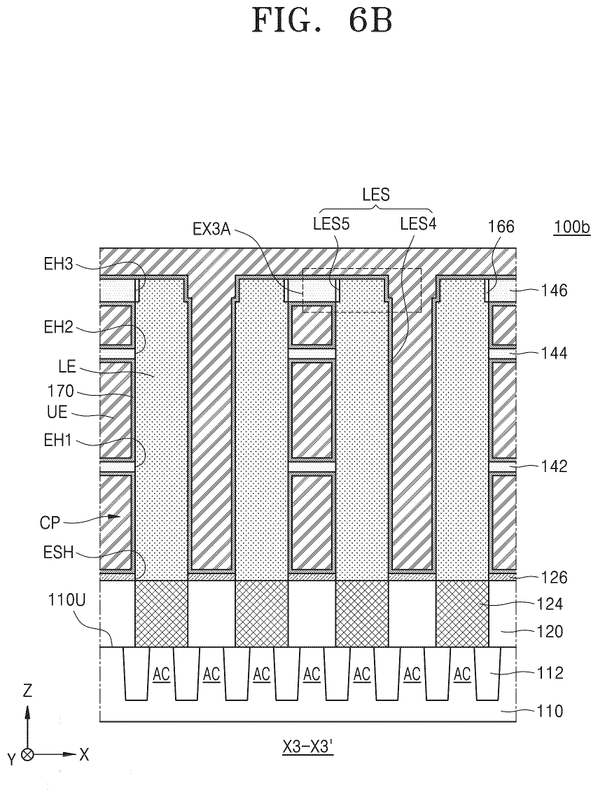

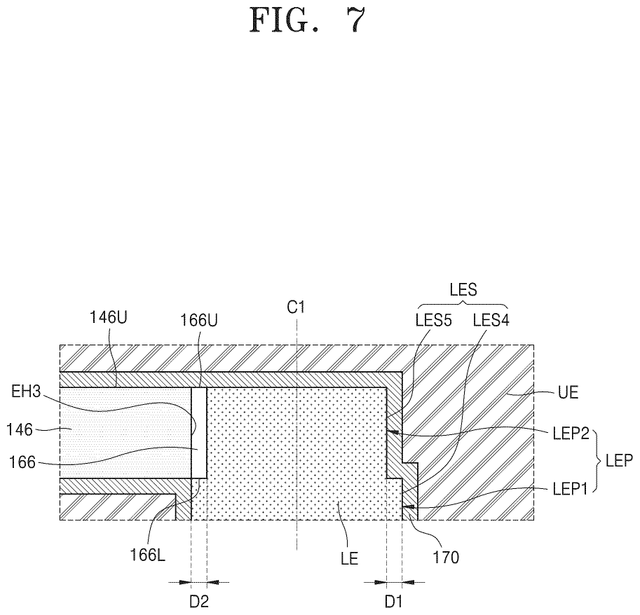

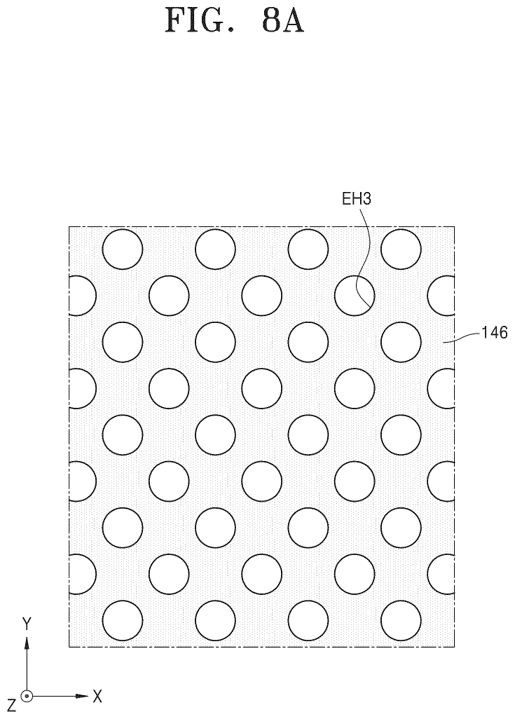

FIG. 6A is a top view illustrating some components of an integrated circuit device 100b according to some implementations. FIG. 6B is a cross-sectional view schematically illustrating some components taken along line X3-X3′ of FIG. 6A. FIG. 7 is a magnified cross-sectional view of an area indicated by “EX3A” in FIG. 6B. In FIGS. 6A to 7, like reference numerals in FIGS. 1 to 3C and 4A to 5C denote like elements, and thus their repetitive description will be omitted.

Referring to FIGS. 6A to 7, each of the plurality of lower electrodes LE of the integrated circuit device 100b includes a lower portion LEP1 individually in contact with each of the plurality of conductive regions 124 and an upper portion LEP2 extending from the lower portion LEP1 and having a width narrower than that of the lower portion LEP1 in the horizontal direction (the X direction and/or the Y direction). In some implementations, the upper portion LEP2 of each of the plurality of lower electrodes LE may be in a corresponding third hole EH3 among the plurality of third holes EH3 of the third insulating support pattern 146.

In some implementations, the sidewall LES of each of the plurality of lower electrodes LE includes a sidewall LES4 of the lower portion LEP1 and a sidewall LES5 of the upper portion LEP2. In some implementations, in a top view, the distance from the center C1 of each of the plurality of lower electrodes LE to the sidewall LES4 of the lower portion LEP1 may be greater than the distance from the center C1 to the sidewall LES5 of the upper portion LEP2. In some implementations, the difference between the distance from the center C1 to the sidewall LES4 of the lower portion LEP1 and the distance from the center C1 to the sidewall LES5 of the upper portion LEP2 may be a first distance D1.

For example, in a top view, an outer boundary of the lower portion LEP1 and an outer boundary of the upper portion LEP2 may have a concentric shape. In some implementations, at the boundary between the lower portion LEP1 and the upper portion LEP2, the sidewall LES of each of the plurality of lower electrodes LE may have a stepped structure.

In some implementations, the lower portions LEP1 of the plurality of lower electrodes LE may extend in the vertical direction (the Z direction) while filling the plurality of lower holes ESH of the etch stop pattern 126, the plurality of first holes EH1 of the first insulating support pattern 142, and the plurality of second holes EH2 of the second insulating support pattern 144. For example, each of the plurality of lower electrodes LE may be in contact with the etch stop pattern 126, the first insulating support pattern 142, and the second insulating support pattern 144. In the integrated circuit device 100b, the plurality of capping patterns 156, the plurality of first bridge patterns 162, and the plurality of second bridge patterns 164 described with reference to FIGS. 1 to 3C may be omitted, and the gap CG1, the first bridge gap GB11, and the second bridge gap GB12 described with reference to FIGS. 3B and 3C may be omitted.

In some implementations, the upper portions LEP2 of the plurality of lower electrodes LE may be individually in the plurality of third holes EH3 of the third insulating support pattern 146, respectively. The integrated circuit device 100b includes a plurality of bridge patterns 166 partially filling the plurality of third holes EH3 and interposed between the third insulating support pattern 146 and the upper portions LEP2 of the plurality of lower electrodes LE. Each of the plurality of bridge patterns 166 may be in contact with the third insulating support pattern 146 and the upper portion LEP2 of a corresponding lower electrode LE among the plurality of lower electrodes LE. The upper portion LEP2 of each of the plurality of lower electrodes LE may be spaced apart from the third insulating support pattern 146 with a corresponding bridge pattern 166 among the plurality of bridge patterns 166 therebetween.

In some implementations, the upper surface of the upper portion LEP2 of each of the plurality of lower electrodes LE may be coplanar with an upper surface 146U of the third insulating support pattern 146. In some implementations, upper surfaces 166U of the plurality of bridge patterns 166 may be at a lower vertical level as that of the upper surfaces the upper portions LPE2 of the plurality of lower electrodes LE and the upper surface 146U of the third insulating support pattern 146. Above each of the plurality of bridge patterns 166, there may be a bridge gap GB limited by the upper surface 166U of the bridge pattern 166, the inner wall of the third hole EH3, and the sidewall LES5 of the upper portion LEP2. In some implementations, the capacitor dielectric layer 170 may fill the bridge gap GB and be in contact with the upper surface 166U of each of the plurality of third bridge patterns 166.

In some implementations, each of the plurality of bridge patterns 166 may overlap the lower portion LEP1 of a corresponding lower electrode LE among the plurality of lower electrodes LE in the vertical direction (the Z direction). In some implementations, a second distance D2 that is the difference between the distance from the center C1 of each of the plurality of lower electrodes LE to the outer wall of a corresponding bridge pattern 166 among the plurality of bridge patterns 166 and the distance from the center C1 to the inner wall of the corresponding bridge pattern 166 may be the same as the first distance D1. In some implementations, the outer wall of each of the plurality of bridge patterns 166 may be on the same curved surface as the sidewall LES4 of the lower portion LEP1 of each of the plurality of lower electrodes LE.

Although FIGS. 7 and 6B illustrate that the lower surface 166L of each of the plurality of bridge patterns 166 is at the same vertical level as that of the lower surface of the third insulating support pattern 146, the technical idea of the disclosure is not limited thereto. In some implementations, the lower surface 166L of each of the plurality of bridge patterns 166 may be at a vertical level higher than the lower surface of the third insulating support pattern 146. In this case, a portion of the sidewall LES4 of the lower portion LEP1 of each of the plurality of lower electrodes LE may be in contact with the third insulating support pattern 146.

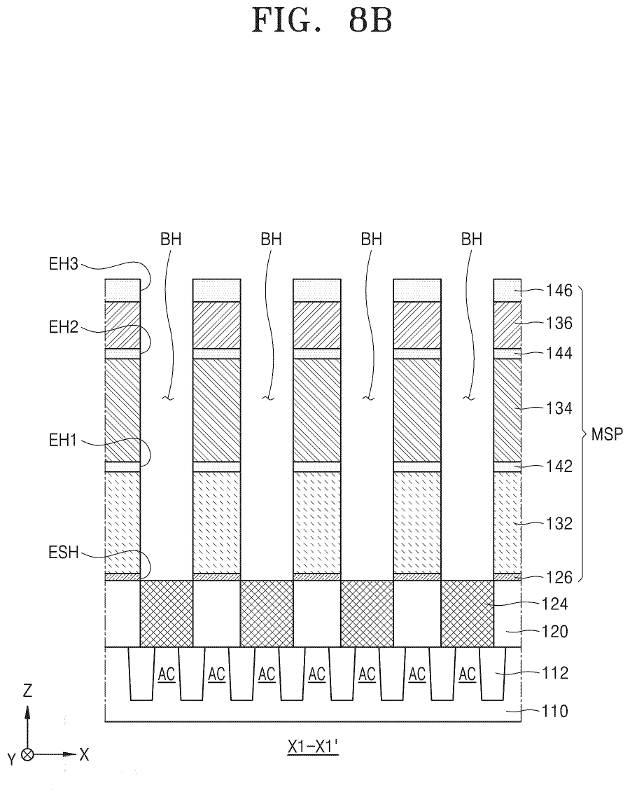

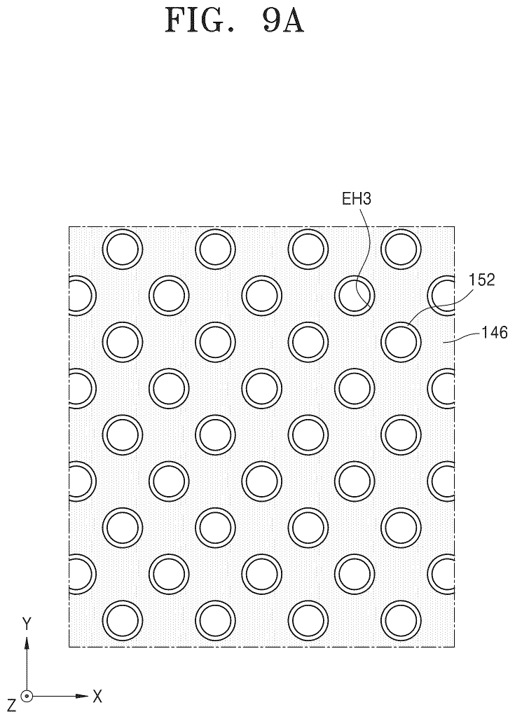

FIGS. 8A to 13 illustrate, in a process order, a method of manufacturing the integrated circuit device 100, according some implementations, wherein FIGS. 8A, 9A, and 11A are top-view layout diagrams illustrating, in the process order, some components to describe the method of manufacturing the integrated circuit device 100, and FIGS. 8B, 9B, 10, 11B, 12, and 13 are cross-sectional views illustrating, in the process order, a portion corresponding to line X1-X1′ of FIG. 2A. In FIGS. 8A to 13, like reference numerals in FIGS. 1 to 3C denote like elements, and thus their repetitive description will be omitted.

Referring to FIGS. 8A and 8B, the lower structure 120 and the conductive region 124 connected to the active region AC through the lower structure 120 may be formed on the substrate 110 having the active region AC defined by the device isolation layer 112. Thereafter, an etch stop layer covering the lower structure 120 and the conductive region 124 may be formed.

The etch stop layer may include an insulating material having an etching selectivity with respect to the lower structure 120. In some implementations, the etch stop layer may include a SiN layer, a SiBN layer, or a combination thereof.

Thereafter, a mold structure formed by alternately stacking a plurality of mold layers and a plurality of support layers one on another may be formed on the etch stop layer. In some implementations, each of the plurality of mold layers may include a material which has a relatively high etch rate for an etching solution including ammonium fluoride (NH₄F), hydrofluoric acid (HF), and water and is thus removable by a lift-off process using the etching solution. In some implementations, each of the plurality of mold layers may include a multi-insulating layer, in which a plurality of boro phospho silicate glass (BPSG) layers, a plurality of SiO layers, and a plurality of SiN layers are alternately stacked one on another, or a SiN layer. However, the constituent material of each of the plurality of mold layers is not limited thereto and may be variously modified and changed within the scope of the technical idea of the disclosure. In some implementations, each of the plurality of support layers may include a SiN layer, a SiBN layer, or a combination thereof.

Thereafter, after forming a mask pattern (not shown) on the mold structure, the mold structure may be anisotropically etched using the mask pattern (not shown) as an etch mask and using the etch stop layer, thereby forming a mold structure pattern MSP limiting a plurality of holes BH. The mold structure pattern MSP includes a first mold pattern 132, the first insulating support pattern 142, a second mold pattern 134, the second insulating support pattern 144, a third mold pattern 136, and the third insulating support pattern 146. In some implementations, the mask pattern (not shown) may include a nitride layer, an oxide layer, a polysilicon layer, a photoresist layer, or a combination thereof.

A process of forming the plurality of holes BH may further include a process of wet-processing a result obtained by anisotropically etching the mold structure. In this process, a portion of the etch stop layer may also be etched, thereby obtaining the etch stop pattern 126 having the plurality of lower holes ESH through which the plurality of conductive regions 124 are exposed. In an illustrative wet processing process, an etching solution including a diluted sulfuric acid peroxide (DSP) solution may be used but is not limited thereto.

In the mold structure pattern MSP, the plurality of first holes EH1 that are portions of the plurality of holes BH may be formed in the first insulating support pattern 142, the plurality of second holes EH2 that are portions of the plurality of holes BH may be formed in the second insulating support pattern 144, and the plurality of third holes EH3 that are portions of the plurality of holes BH may be formed in the third insulating support pattern 146.

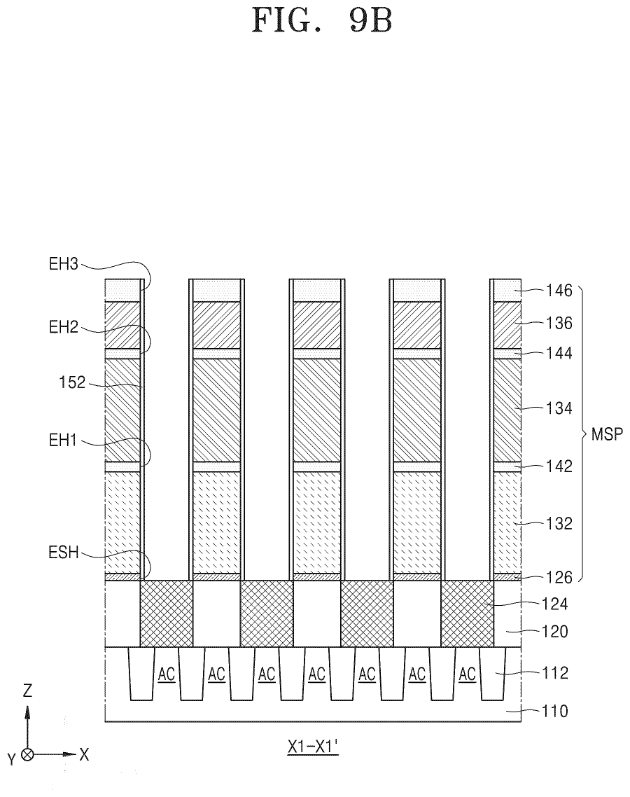

Referring to FIGS. 9A and 9B, in the result of FIGS. 8A and 8B, the mask pattern (not shown) may be removed, and a spacer layer conformally covering the mold structure pattern MSP may be formed. For example, the spacer layer may cover the upper surface of the third insulating support pattern 146 and the inner walls and the bottom surfaces of the plurality of holes BH. In some implementations, an atomic layer deposition (ALD) process may be used to form the spacer layer. According to the thickness of the spacer layer, the horizontal width of the lower electrode LE to be formed in a subsequent process may be adjusted.

In some implementations, the spacer layer may include a material having an etch selectivity with respect to the first mold pattern 132, the second mold pattern 134, and the third mold pattern 136. In some implementations, the spacer layer may include a material of which the etch rate for an etchant varies as a result of changing a property of matter in a subsequent ashing process. In some implementations, the spacer layer may include a carbon-containing insulating material. For example, the spacer layer may include silicon oxycarbide (SiOC), silicon oxycarbonitride (SiOCN), or a combination thereof.

Thereafter, atomic layer etching may be performed to remove, from the spacer layer, portions covering the bottom surfaces of the plurality of holes BH and a portion covering the upper surface of the third insulating support pattern 146, thereby forming a plurality of spacer patterns 152. In this process, the upper surfaces of the plurality of conductive regions 124 may be exposed. For example, the plurality of spacer patterns 152 may individually cover the inner walls of the plurality of holes BH, respectively. In some implementations, neutral beam etching may be used to expose the upper surfaces of the plurality of conductive regions 124.

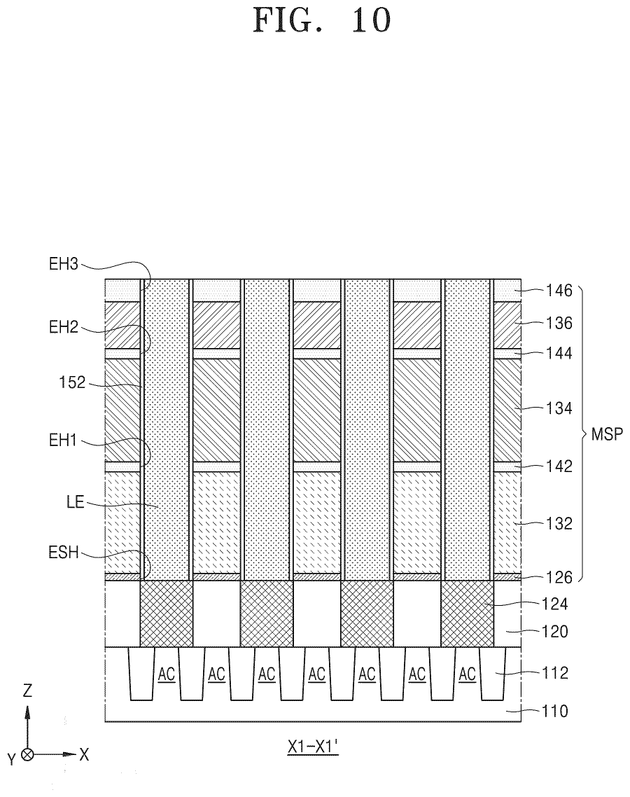

Referring to FIG. 10, in the result of FIGS. 9A and 9B, the plurality of lower electrodes LE filling the plurality of holes BH (see FIG. 9B) may be formed.

In some implementations, to form the plurality of lower electrodes LE, in the result of FIG. 9B, a conductive layer filling the plurality of holes BH (see FIG. 9B) and covering the upper surface of the third insulating support pattern 146 and the upper surfaces of the plurality of spacer patterns 152 (see FIG. 9A). An ALD process may be used to form the conductive layer. Thereafter, an etchback process or a chemical mechanical polishing (CMP) process may be used to remove a portion of the conductive layer until the upper surface of the third insulating support pattern 146 and the upper surfaces of the plurality of spacer patterns 152 (see FIG. 9A) are exposed, thereby forming the plurality of lower electrodes LE. For example, the upper surfaces of the plurality of lower electrodes LE may be coplanar with the upper surface of the third insulating support pattern 146 and the upper surfaces of the plurality of spacer patterns 152 (see FIG. 9A).

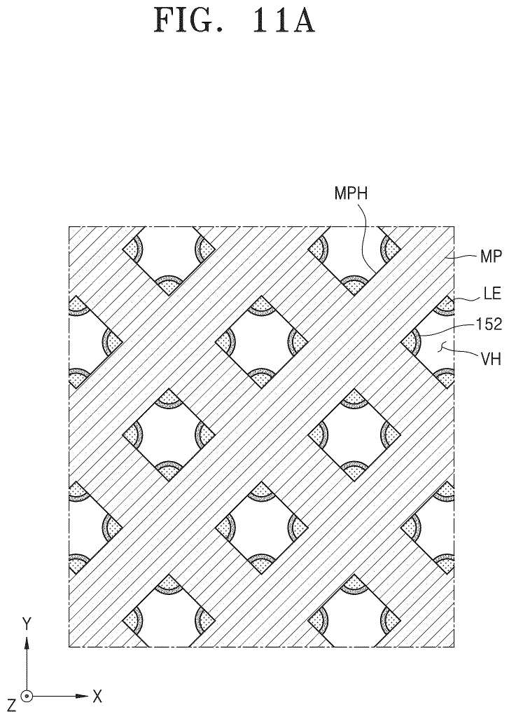

Referring to FIGS. 11A and 11B, in the result of FIG. 10, a mask pattern MP having a plurality of mask holes MPH through which each of the upper surfaces of the plurality of lower electrodes LE, the upper surface of the third insulating support pattern 146, and the upper surfaces of the plurality of spacer patterns 152 is partially exposed may be formed. The plurality of mask holes MPH may correspond to, for example, the plane shape of the plurality of third integrated holes IH3 described with reference to FIG. 2A.

In some implementations, the mask pattern MP may have an etch selectivity with respect to the plurality of lower electrodes LE and the plurality of spacer patterns 152. In some implementations, the mask pattern MP may include an amorphous carbon layer (ACL). In some implementations, the mask pattern MP may further include a nitride layer, an oxide layer, a polysilicon layer, a photoresist layer, or a combination thereof in addition to the ACL.

Thereafter, the third mold pattern 136 (see FIG. 10) may be exposed by using the mask pattern MP as an etch mask to remove portions of the third insulating support pattern 146 exposed through the plurality of mask holes MPH, and then the third mold pattern 136 (see FIG. 10) may be removed by wet etching. Thereafter, the second mold pattern 134 (see FIG. 10) may be exposed by removing portions of the second insulating support pattern 144 exposed through the plurality of mask holes MPH, and then the second mold pattern 134 (see FIG. 10) may be removed by wet etching. Thereafter, the first mold pattern 132 (see FIG. 10) may be exposed by removing portions of the first insulating support pattern 142 exposed through the plurality of mask holes MPH, and then the first mold pattern 132 (see FIG. 10) may be removed by wet etching. After removing the first mold pattern 132 (see FIG. 10), the second mold pattern 134 (see FIG. 10), and the third mold pattern 136 (see FIG. 10), the sidewalls of the plurality of spacer patterns 152 may be exposed. In some implementations, a plurality of vertical holes VH vertically overlapping the plurality of mask holes MPH, respectively, and a horizontal hole LH vertically overlapping the mask pattern MP may be formed. For example, the upper surface of the etch stop pattern 126 may be exposed through the plurality of vertical holes VH and the horizontal hole LH, and the upper and lower surfaces of the first insulating support pattern 142, the upper and lower surfaces of the second insulating support pattern 144, and the lower surface of the third insulating support pattern 146 may be exposed through the horizontal hole LH.

In some implementations, an etching solution including NH₄F, HF, and water may be used to wet-removing the first mold pattern 132, the second mold pattern 134, and the third mold pattern 136 but is not limited thereto.

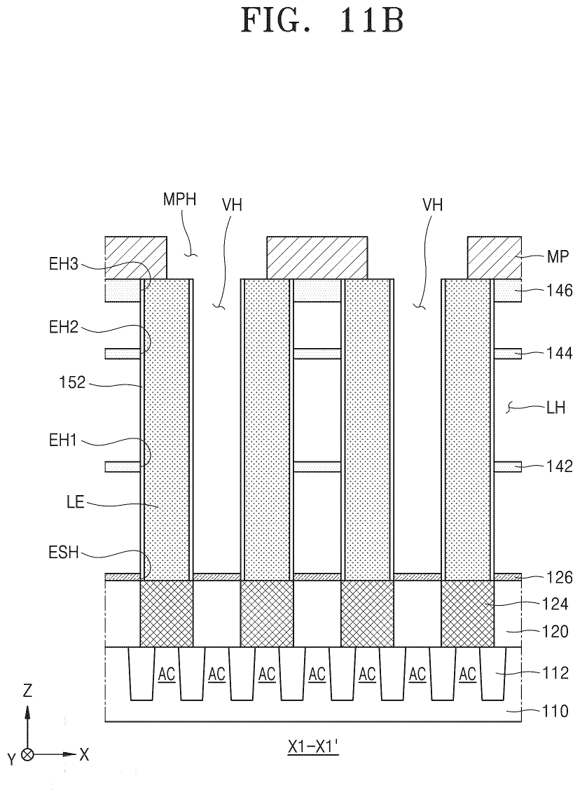

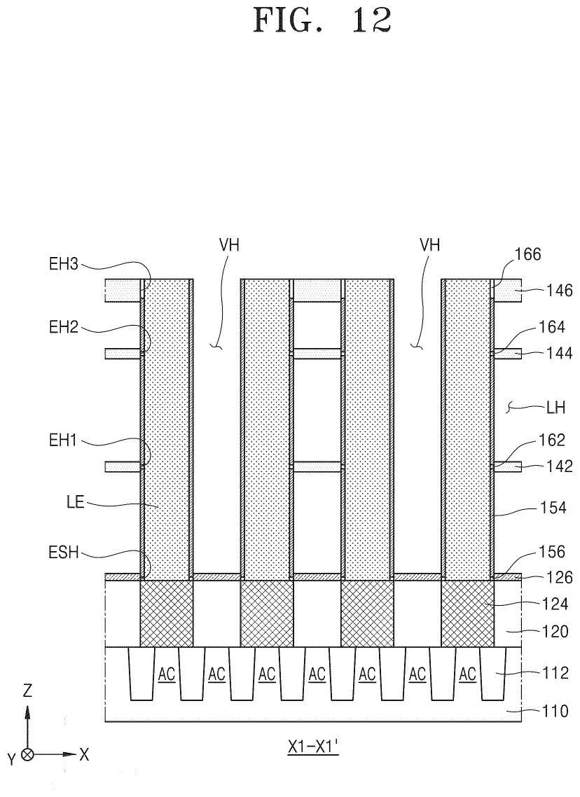

Referring to FIG. 12, in the result of FIGS. 11A and 11B, an ashing process may be performed to convert a portion of each of the plurality of spacer patterns 152 (see FIG. 11A) into a sacrificial pattern 154 and form the plurality of capping patterns 156, the plurality of first bridge patterns 162, the plurality of second bridge patterns 164, and the plurality of third bridge patterns 166.

In some implementations, in each of the plurality of spacer patterns 152 (see FIG. 11A), portions exposed through the horizontal hole LH between the etch stop pattern 126 and the first insulating support pattern 142, between the first insulating support pattern 142 and the second insulating support pattern 144, and between the second insulating support pattern 144 and the third insulating support pattern 146 and a portion exposed through each of the plurality of vertical holes VH may be converted into the sacrificial pattern 154. In some implementations, in the plurality of spacer patterns 152 (see FIG. 11A), portions, which are not exposed by the plurality of vertical holes VH and the horizontal hole LH by being interposed between the etch stop pattern 126 and the plurality of lower electrodes LE, between the first insulating support pattern 142 and the plurality of lower electrodes LE, between the second insulating support pattern 144 and the plurality of lower electrodes LE, and between the third insulating support pattern 146 and the plurality of lower electrodes LE, may remain without being converted, thereby forming the plurality of capping patterns 156 and the plurality of first to third bridge patterns 162, 164, and 166.

In some implementations, gas used in the ashing process may include mixed gas of dihydrogen (H₂) and dinitrogen (N₂). In some implementations, the sacrificial pattern 154 may be a portion obtained by removing carbon (C) from the plurality of spacer patterns 152 (see FIG. 11A) through the ashing process, and the plurality of capping patterns 156, the plurality of first bridge patterns 162, the plurality of second bridge patterns 164, and the plurality of third bridge patterns 166 may be portions of the plurality of spacer patterns 152 (see FIG. 11A) from which C has not been removed through the ashing process. In some implementations, the mask pattern MP (see FIG. 11B) may be removed in the ashing process. In some implementations, the sacrificial pattern 154 may include a material different from that of the plurality of capping patterns 156, the plurality of first bridge patterns 162, the plurality of second bridge patterns 164, and the plurality of third bridge patterns 166 and have an etch selectivity with respect to the same. For example, the sacrificial pattern 154 may include a SiO layer, a SiON layer, or a combination thereof.

In some implementations, removal of C through the ashing process may be achieved through spread occurring on exposed surfaces of the plurality of spacer patterns 152 (see FIG. 11B), and accordingly, in the plurality of spacer patterns 152 (see FIG. 11B), boundary portions between the first to third insulating support patterns 142, 144, and 146 and the plurality of lower electrodes LE but adjacent to the plurality of vertical holes VH and the horizontal hole LH and boundary portions between the plurality of capping patterns 156 and the plurality of lower electrodes LE but adjacent to the plurality of vertical holes VH and the horizontal hole LH may be converted into the sacrificial pattern 154. The boundary portions may be removed in a subsequent process to form the gap CG1, the first bridge gap GB11, the second bridge gap GB12, and the bridge gap GB3 described with reference to FIGS. 2B and 3A to 3C. Because the upper surfaces of the plurality of third bridge patterns 166 are not exposed by being covered by the mask pattern MP (see FIG. 11B) while performing the ashing process, upper portions of the plurality of third bridge patterns 166 may not be converted into the sacrificial pattern 154 and not be removed even in a subsequent process.

Referring to FIG. 13, in the result of FIG. 12, the sacrificial pattern 154 (see FIG. 12) may be removed by performing a wet process using an etching solution including HF. By removing the sacrificial pattern 154 (see FIG. 12) exposed through the plurality of vertical holes VH (see FIG. 12), the plurality of first integrated holes IH1 of the first insulating support pattern 142, the plurality of second integrated holes IH2 of the second insulating support pattern 144, and the plurality of third integrated holes IH3 of the third insulating support pattern 146 may be formed. In some implementations, the sacrificial pattern 154 (see FIG. 12) may be removed to form the first bridge gap GB11, the second bridge gap GB12, and the bridge gap GB3 described with reference to FIGS. 2B and 3A to 3C on and/or beneath the plurality of capping patterns 156 and the plurality of first to third bridge patterns 162, 164, and 166.

Referring to FIGS. 13 and 2A to 3C, the capacitor dielectric layer 170 covering the etch stop pattern 126, the plurality of lower electrodes LE, the plurality of capping patterns 156, the first to third insulating support patterns 142, 144, and 146, and the plurality of first to third bridge patterns 162, 164, and 166 may be formed on the result of FIG. 13. In some implementations, an ALD process may be used to form the capacitor dielectric layer 170. The capacitor dielectric layer 170 may include hafnium dioxide (HfO₂), zirconium dioxide (ZrO₂), aluminum oxide (Al₂O₃), lanthanum oxide (La₂O₃), tantalum oxide (Ta₂O₃), niobium oxide (Nb₂O₅), cerium dioxide (CeO₂), titanium dioxide (TiO₂), germanium dioxide (GeO₂), or a combination thereof but is not limited thereto.

Thereafter, the upper electrode UE covering the capacitor dielectric layer 170 may be formed to manufacture the integrated circuit device 100. In some implementations, to form the upper electrode UE, a chemical vapor deposition (CVD), metalorganic chemical vapor deposition (MOCVD), physical vapor deposition (PVD), or ALD process may be used.

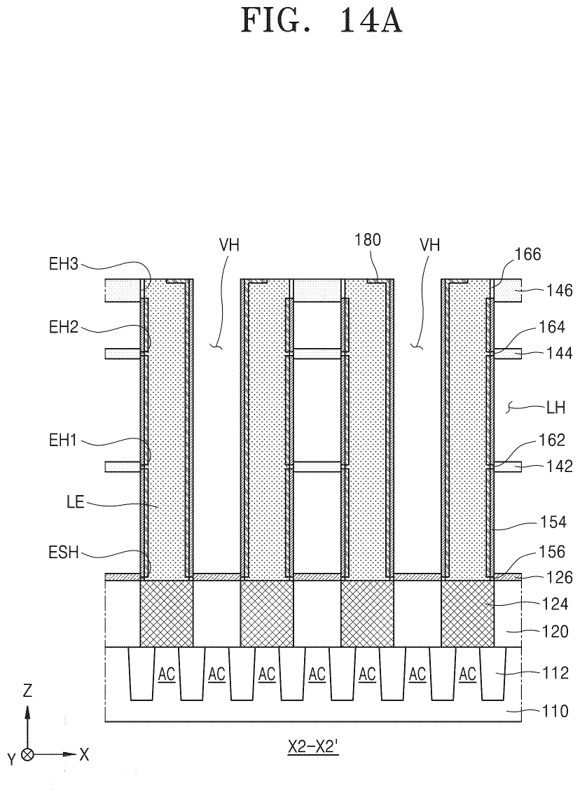

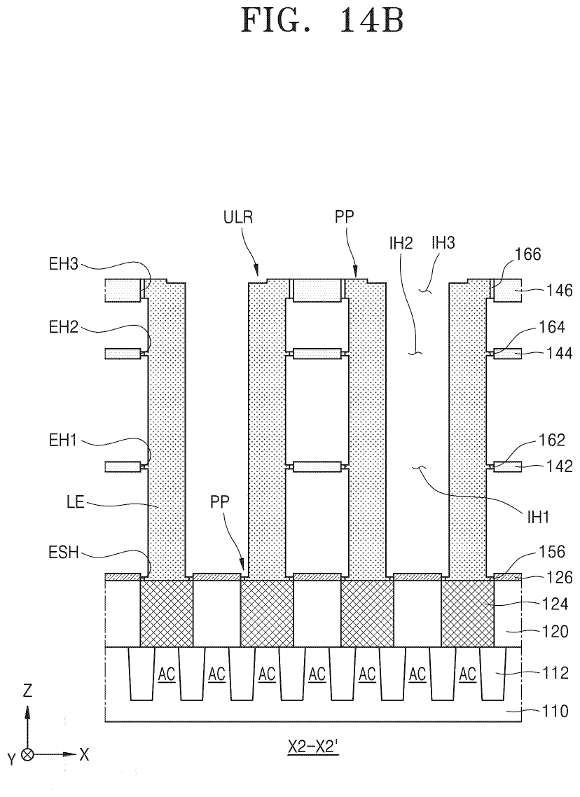

FIGS. 14A and 14B are cross-sectional views illustrating, in a process order, a portion corresponding to line X2-X2′ of FIG. 4A to describe a method of manufacturing the integrated circuit device 100a, according to some implementations. In FIGS. 14A and 14B, like reference numerals in FIGS. 1 to 13 denote like elements, and thus their repetitive description will be omitted.

In the same manner as described with reference to FIGS. 8A to 11B, up to a process of forming the plurality of vertical holes VH and the horizontal hole LH through which the upper surface of the etch stop pattern 126, the upper and lower surfaces of the first insulating support pattern 142, the upper and lower surfaces of the second insulating support pattern 144, and the lower surface of the third insulating support pattern 146 are exposed may be performed.

Referring to FIG. 14A, in the result of FIGS. 11A and 11B, an ashing process may be performed to convert a portion of each of the plurality of spacer patterns 152 (see FIG. 11A) into a sacrificial pattern 154 and form the plurality of capping patterns 156, the plurality of first bridge patterns 162, the plurality of second bridge patterns 164, and the plurality of third bridge patterns 166. In this process, a portion of an exposed portion of each of the plurality of lower electrodes LE may be converted into an oxide layer 180. In some implementations, gas used in the ashing process may include dioxygen (O₂).

In each of the plurality of spacer patterns 152 (see FIG. 11A), portions exposed through the horizontal hole LH between the etch stop pattern 126 and the first insulating support pattern 142, between the first insulating support pattern 142 and the second insulating support pattern 144, and between the second insulating support pattern 144 and the third insulating support pattern 146 and a portion exposed through each of the plurality of vertical holes VH may be converted into the sacrificial pattern 154. In the ashing process, portions of the sidewalls of the plurality of lower electrodes LE in contact with the sacrificial pattern 154 and portions of the upper surfaces of the plurality of lower electrodes LE, which do not overlap the mask pattern MP (see FIGS. 11A and 11B), may be converted into the oxide layer 180.

Referring to FIG. 14B, a wet process using an etching solution including HF may be performed on the result of FIG. 14A to remove the sacrificial pattern 154 (see FIG. 12) and the oxide layer 180 (see FIG. 14A), thereby forming the plurality of protrusion portions PP. In some implementations, in the wet process, a portion of the oxide layer 180 (see FIG. 14A), which is formed on the upper surface of each of the plurality of lower electrodes LE, may be removed, thereby forming the recess ULR.

According to the removal of the sacrificial pattern 154 (see FIG. 12), the plurality of first integrated holes IH1 of the first insulating support pattern 142, the plurality of second integrated holes IH2 of the second insulating support pattern 144, and the plurality of third integrated holes IH3 of the third insulating support pattern 146 may be formed. In some implementations, the sacrificial pattern 154 (see FIG. 12) may be removed to form the first bridge gap GB11, the second bridge gap GB12, and the bridge gap GB3 described with reference to FIGS. 2B and 3A to 3C on and/or beneath the plurality of capping patterns 156 and the plurality of first to third bridge patterns 162, 164, and 166.

Referring to FIGS. 14B and 4A to 5C, the capacitor dielectric layer 170 covering the etch stop pattern 126, the plurality of lower electrodes LE, the plurality of capping patterns 156, the first to third insulating support patterns 142, 144, and 146, and the plurality of first to third bridge patterns 162, 164, and 166 may be formed on the result of FIG. 14B. Thereafter, the upper electrode UE covering the capacitor dielectric layer 170 may be formed to manufacture the integrated circuit device 100a.

FIGS. 15A to 15E are cross-sectional views illustrating, in a process order, a portion corresponding to line X3-X3′ of FIG. 6A to describe a method of manufacturing the integrated circuit device 100b, according to some implementations. In FIGS. 15A to 15E, like reference numerals in FIGS. 1 to 14B denote like elements, and thus their repetitive description will be omitted.

In the same manner as described with reference to FIGS. 9A and 9B, the mold structure pattern MSP limiting the plurality of holes BH may be formed.

Referring to FIG. 15A, in the result of FIGS. 9a and 9B, a covering layer 151 covering an upper portion of the mold structure pattern MSP may be formed. In some implementations, the covering layer 151 may be formed using a step coverage in a deposition process. For example, a CVD process or the like may be used to form the covering layer 151, but the technical idea of the disclosure is not limited thereto. In some implementations, the covering layer 151 may cover the upper surface of the third insulating support pattern 146 and an upper portion of the inner wall of each of the plurality of holes BH.

Although FIG. 15A illustrates that the covering layer 151 covers the upper surface and the sidewall of the third insulating support pattern 146, the covering layer 151 is not limited thereto. For example, the covering layer 151 may cover the upper surface and a portion of the sidewall of the third insulating support pattern 146. For example, the covering layer 151 may cover the upper surface and the sidewall of the third insulating support pattern 146 and the sidewall of the third mold pattern 136. Although FIG. 15A shows that the thickness of the covering layer 151 is uniform, the covering layer 151 is not limited thereto. For example, the thickness of a portion of the covering layer 151 covering the upper surface of the third insulating support pattern 146 may be greater than the thickness of a portion of the covering layer 151 covering the sidewall of the third insulating support pattern 146. For example, the thickness of a portion of the covering layer 151 covering an upper portion of each of the plurality of holes BH may gradually decrease toward the upper surface of the substrate 110.

Referring to FIG. 15B, in the result of FIG. 15A, a conductive layer filling the plurality of holes BH (see FIG. 15A) and covering the upper surface of the third insulating support pattern 146 and the upper surface of the covering layer 151 (see FIG. 15A) may be formed. An ALD process may be used to form the conductive layer. Thereafter, an etchback process or a CMP process may be used to remove a portion of the conductive layer and a portion of the covering layer 151 until the upper surface of the third insulating support pattern 146 is exposed, thereby forming the plurality of lower electrodes LE and a plurality of covering patterns 153. In some implementations, each of the plurality of covering patterns 153 may individually cover an upper portion of the inner wall of each of the plurality of holes BH (see FIG. 15A) and be in contact with a corresponding lower electrode LE among the plurality of lower electrodes LE. In some implementations, the upper surfaces of the plurality of lower electrodes LE may be coplanar with the upper surface of the third insulating support pattern 146 and the upper surfaces of the plurality of covering patterns 153.

In some implementations, the plurality of lower electrodes LE may extend in the vertical direction (the Z direction) by passing through the plurality of lower holes ESH of the etch stop pattern 126, the plurality of first holes EH1 of the first insulating support pattern 142, the plurality of second holes EH2 of the second insulating support pattern 144, and the plurality of third holes EH3 of the third insulating support pattern 146. Each of the plurality of lower electrodes LE may be in contact with the etch stop pattern 126, the first insulating support pattern 142, and the second insulating support pattern 144. In some implementations, the top portion of each of the plurality of lower electrodes LE may be individually surrounded by each of the plurality of covering patterns 153 in a top view. In some implementations, the top portion of each of the plurality of lower electrodes LE may be spaced apart from the third insulating support pattern 146 with each of the plurality of covering patterns 153 therebetween.

Referring to FIG. 15C, in the result of FIG. 15B, the mask pattern MP having the plurality of mask holes MPH through which each of the upper surfaces of the plurality of lower electrodes LE, the upper surface of the third insulating support pattern 146, and the upper surfaces of the plurality of covering patterns 153 is partially exposed may be formed.

Thereafter, the third mold pattern 136 (see FIG. 15B) may be exposed by using the mask pattern MP as an etch mask to remove portions of the third insulating support pattern 146 exposed through the plurality of mask holes MPH, and then the third mold pattern 136 (see FIG. 15B) may be removed by wet etching. Thereafter, the second mold pattern 134 (see FIG. 15B) may be exposed by removing portions of the second insulating support pattern 144 exposed through the plurality of mask holes MPH, and then the second mold pattern 134 (see FIG. 15B) may be removed by wet etching. Thereafter, the first mold pattern 132 (see FIG. 15B) may be exposed by removing portions of the first insulating support pattern 142 exposed through the plurality of mask holes MPH, and then the first mold pattern 132 (see FIG. 15B) may be removed by wet etching.

In some implementations, the plurality of vertical holes VH vertically overlapping the plurality of mask holes MPH and the horizontal hole LH vertically overlapping the mask pattern MP may be formed by removing portions of the first to third insulating support patterns 142, 144, and 146 and the first to third mold patterns 132, 134, and 136.

In some implementations, an etching solution including NH₄F, HF, and water may be used to wet-removing the first mold pattern 132, the second mold pattern 134, and the third mold pattern 136 but is not limited thereto.

Referring to FIG. 15D, an ashing process may be performed on the result of FIG. 15C to convert a portion of each of the plurality of covering patterns 153 (see FIG. 15C) into a sacrificial pattern 155 and form the plurality of bridge patterns 166. In some implementations, gas used in the ashing process may include mixed gas of H₂ and N₂.

The sacrificial pattern 155 may be formed by removing, in the ashing process, C from a portion of each of the plurality of covering patterns 153 (see FIG. 15C) vertically overlapping a corresponding mask hole MPH. The other portion of each of the plurality of covering patterns 153 (see FIG. 15C) vertically overlapping the mask pattern MP (see FIG. 15C) and in contact with the third insulating support pattern 146 may be formed as a bridge pattern 166.

Referring to FIG. 15E, in the result of FIG. 15D, the sacrificial pattern 155 (see FIG. 15D) may be removed by performing a wet process using an etching solution including HF. By removing the sacrificial pattern 155 (see FIG. 15D) exposed through each of the plurality of vertical holes VH (see FIG. 15D), the plurality of first integrated holes IH1 of the first insulating support pattern 142 may be formed. In some implementations, by removing the sacrificial pattern 155 (see FIG. 15D), the bridge gap GB described with reference to FIG. 7 may be formed on and/or beneath each of the plurality of bridge patterns 166.

Referring to FIGS. 15E and 6A to 7, the capacitor dielectric layer 170 covering the etch stop pattern 126, the plurality of lower electrodes LE, the plurality of capping patterns 156, the first to third insulating support patterns 142, 144, and 146, and the plurality of bridge patterns 166 may be formed on the result of FIG. 15E. Thereafter, the upper electrode UE covering the capacitor dielectric layer 170 may be formed to manufacture the integrated circuit device 100b.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the disclosure has been particularly shown and described with reference some implementations thereof, it will be understood that various changes in form and details may be made therein without departing from the spirit and scope of the following claims.

What is claimed is:

1. An integrated circuit device comprising:
a lower electrode above a substrate;
a plurality of insulating support patterns supporting the lower electrode and spaced apart from each other in a vertical direction;
a plurality of bridge patterns respectively interposed between the plurality of insulating support patterns and the lower electrode, wherein a thickness of each bridge pattern of the plurality of bridge patterns is less than a thickness of a corresponding insulating support pattern of the plurality of insulating support patterns in the vertical direction;
a capacitor dielectric layer covering the lower electrode, the plurality of insulating support patterns, and the plurality of bridge patterns; and
an upper electrode facing the lower electrode, wherein the capacitor dielectric layer is arranged between the upper electrode and the lower electrode.

2. The integrated circuit device of claim 1, wherein the plurality of insulating support patterns comprise an upper insulating support pattern at a top of the plurality of insulating support patterns, and an upper surface of the lower electrode is coplanar with an upper surface of the upper insulating support pattern.

3. The integrated circuit device of claim 1, wherein the plurality of insulating support patterns comprise an upper insulating support pattern at a top of the plurality of insulating support patterns, the plurality of bridge patterns comprise an upper bridge pattern in contact with the upper insulating support pattern and the lower electrode, an upper surface of the upper insulating support pattern is coplanar with an upper surface of the upper bridge pattern, and a lower surface of the upper insulating support pattern is at a vertical level lower than a lower surface of the upper bridge pattern.

4. The integrated circuit device of claim 1, wherein the plurality of insulating support patterns comprise a lower insulating support pattern that is closest to an upper surface of the substrate among the plurality of insulating support patterns, the plurality of bridge patterns comprise a lower bridge pattern in contact with the lower insulating support pattern and the lower electrode, an upper surface of the lower insulating support pattern is at a vertical level higher than an upper surface of the lower bridge pattern, and a lower surface of the lower insulating support pattern is at a vertical level lower than a lower surface of the lower bridge pattern.

5. The integrated circuit device of claim 1, wherein the plurality of bridge patterns have an open ring shape.

6. The integrated circuit device of claim 1, further comprising:
an etch stop pattern surrounding a lower end portion of the lower electrode under the plurality of insulating support patterns; and
a capping pattern between the etch stop pattern and the lower electrode,
wherein an upper surface of the capping pattern is at a vertical level lower than an upper surface of the etch stop pattern.

7. The integrated circuit device of claim 6, wherein the capping pattern has a closed ring shape.

8. The integrated circuit device of claim 1, wherein a sidewall of the lower electrode comprises a first portion facing the plurality of insulating support patterns and a second portion facing the upper electrode, and a first distance from a center of the lower electrode to the first portion is greater than a second distance from the center of the lower electrode to the second portion.

9. The integrated circuit device of claim 8, wherein an upper surface of the lower electrode vertically overlaps a region between the center of the lower electrode and the second portion.

10. An integrated circuit device comprising:
an upper insulating support pattern spaced apart from an upper surface of a substrate in a vertical direction, wherein the upper insulating support pattern has a plurality of holes;
a plurality of lower electrodes extending above the substrate in the vertical direction through the plurality of holes, respectively;
a plurality of upper bridge patterns between the upper insulating support pattern and the plurality of lower electrodes in the plurality of holes, respectively;
a capacitor dielectric layer covering the upper insulating support pattern, the plurality of lower electrodes, and the plurality of upper bridge patterns; and
an upper electrode facing the plurality of lower electrodes, wherein the capacitor dielectric layer is arranged between the upper electrode and the plurality of lower electrodes,
wherein each of the plurality of lower electrodes comprises an upper portion in a corresponding hole of the plurality of holes and a lower portion extending downward from the upper portion in the vertical direction, the lower portion having a horizontal width narrower than a horizontal width of the upper portion.

11. The integrated circuit device of claim 10, wherein upper surfaces of the plurality of lower electrodes are coplanar with an upper surface of the upper insulating support pattern.

12. The integrated circuit device of claim 10, wherein upper surfaces of the plurality of upper bridge patterns are coplanar with an upper surface of the upper insulating support pattern.

13. The integrated circuit device of claim 10, wherein an outer boundary of the lower portion and an outer boundary of the upper portion are concentric.

14. The integrated circuit device of claim 12, wherein a difference between a distance from a center of each of the plurality of lower electrodes to a sidewall of the lower portion and a distance from the center to the upper portion is a first length, each of the plurality of upper bridge patterns comprises an outer wall in contact with the upper insulating support pattern and an inner wall in contact with a corresponding lower electrode among the plurality of lower electrodes, and the first length is equal to a second distance, the second distance being a difference between a distance from the center to the outer wall and a distance from the center to the inner wall.

15. The integrated circuit device of claim 10, further comprising a plurality of lower insulating support patterns spaced apart from each other in the vertical direction between the substrate and the upper insulating support pattern, wherein the plurality of lower insulating support patterns are configured to support the plurality of lower electrodes.

16. The integrated circuit device of claim 15, wherein the plurality of lower insulating support patterns are in contact with the plurality of lower electrodes, respectively.

17. An integrated circuit device comprising:
a substrate including an active region;
a plurality of conductive regions formed on the active region;
an etch stop pattern extending in a horizontal direction on the plurality of conductive regions and having a plurality of lower holes vertically overlapping the plurality of conductive regions, respectively;
a plurality of lower electrodes connected to the plurality of conductive regions through the plurality of lower holes, respectively;
a plurality of capping patterns between the etch stop pattern and the plurality of lower electrodes in the plurality of lower holes, respectively;
an upper insulating support pattern extending in the horizontal direction at a location spaced apart from the etch stop pattern in a vertical direction, the upper insulating support pattern having a plurality of holes accommodating the plurality of lower holes, respectively;
a plurality of upper bridge patterns between the plurality of lower electrodes and the upper insulating support pattern in the plurality of holes, respectively, wherein each upper bridge pattern of the plurality of upper bridge patterns has a thickness in the vertical direction less than a thickness of the upper insulating support pattern in the vertical direction;
a capacitor dielectric layer covering the plurality of lower electrodes, the etch stop pattern, the plurality of capping patterns, the upper insulating support pattern, and the plurality of upper bridge patterns; and
an upper electrode facing the plurality of lower electrodes, wherein the capacitor dielectric layer is arranged between the upper electrode facing and the plurality of lower electrodes.

18. The integrated circuit device of claim 17, wherein upper surfaces of the plurality of lower electrodes are coplanar with an upper surface of the upper insulating support pattern.

19. The integrated circuit device of claim 17, wherein upper surfaces of the plurality of upper bridge patterns are coplanar with upper surfaces of the plurality of lower electrodes, and lower surfaces of the plurality of upper bridge patterns are at a vertical level higher than the upper insulating support pattern.

20. The integrated circuit device of claim 17, wherein a sidewall of each of the plurality of lower electrodes comprises a first portion facing the upper electrode, each of the plurality of lower electrodes comprises a protrusion portion protruding from the first portion in a direction away from a center of that lower electrode, and the protrusion portion is in contact with a corresponding upper bridge pattern among the plurality of upper bridge patterns in a corresponding hole among the plurality of holes.
